(19) United States
(12) Patent Application Publication
(10) Pub. No.: US 2026/0371766 A1
(43) Pub. Date: Nov. 19, 2026

(54) OPTICAL DETECTION DEVICE AND ELECTRONIC APPARATUS

(71) Applicant: SONY SEMICONDUCTOR SOLUTIONS CORPORATION, KANAGAWA (JP)

(72) Inventor: Hajime YAMAGISHI, KANAGAWA (JP)

(21) Appl. No.: 19/136,386

(22) PCT Filed: Nov. 7, 2023
(86) PCT No.: PCT/JP2023/040092

§ 371 Date: Jun. 6, 2025

(30) Foreign Application Priority Data
Dec. 15, 2022 (JP) 2022-199933

(51) Int. Cl. H10F 39/00; H10W 42/20

(52) U.S. Cl. CPC H10F 39/811; H10F 39/809; H10W 42/271

(57) ABSTRACT

Reduction of crosstalk is achieved. An optical detection device includes a first semiconductor layer that has first and second surfaces located at positions opposite to each other and includes a photoelectric conversion portion for photoelectrically converting light entering from the second surface side, a second semiconductor layer that includes a transistor, and is provided on the first surface side of the first semiconductor layer, a third semiconductor layer that includes a transistor, and is provided on the side opposite to the first semiconductor layer side of the second semiconductor layer and overlapped with the second semiconductor layer, and a shielding body provided between the second semiconductor layer and the third semiconductor layer.

### TECHNICAL FIELD

The present technology (the technology according to the present disclosure) relates to an optical detection device and an electronic apparatus, and particularly to a technology effective when applied to an optical detection device having semiconductor layers laminated in a plurality of stages and an electronic apparatus including this optical detection device.

### BACKGROUND ART

A laminated optical detection device known as a type of optical detection device, such as a solid-state imaging device and a distance measuring device, includes semiconductor layers laminated in a plurality of stages and each provided as a layer where an element is formed. This laminated optical detection device is capable of transferring signals at high speed. PTL 1 discloses a solid-state imaging device having a double-layered structure where two semiconductor layers are laminated. In addition, PTL 1 also discloses a technology which provides a light shielding member for shielding entrance of light emitted from an active element into a photoelectric conversion portion during operation of the active element.

In addition, PTL 2 discloses a solid-state imaging device which has a triple-layered structure including three semiconductor layers in an upper stage, a middle stage, and a lower stage. The semiconductor layer in the upper stage contains a photoelectric conversion portion. Each of the semiconductor layers in the middle and lower stages contains transistors constituting a pixel circuit (read circuit) for outputting a pixel signal corresponding to signal charge photoelectrically converted by the photoelectric conversion portion, a logic circuit for processing the pixel signal output from the pixel circuit, and others.

### CITATION LIST

### Patent Literature

### PTL 1

JP 2012-64709A

### PTL 2

JP 2021-7176A

### SUMMARY

### Technical Problem

As noted above, the optical detection device having the triple-layered structure includes the transistors constituting the logic circuit in each of the semiconductor layers in the middle stage and the lower stage. In this case, noise generated during operation of the transistors contained in one of the semiconductor layers in the lower stage and the middle stage may propagate to the transistors contained in the other semiconductor layer, and cause crosstalk which influences operation of the transistors in the other semiconductor layer.

The present technology has been developed in consideration of the above-mentioned circumstances, and provides an optical detection device and an electronic apparatus capable of reducing crosstalk.

### Solution to Problem

(1)

An optical detection device according to an aspect of the present technology includes a first semiconductor layer that has first and second surfaces located at positions opposite to each other and includes a photoelectric conversion portion for photoelectrically converting light entering from the second surface side, a second semiconductor layer that includes a transistor, and is provided on the first surface side of the first semiconductor layer, a third semiconductor layer that includes a transistor, and is provided on a side opposite to the first semiconductor layer side of the second semiconductor layer and overlapped with the second semiconductor layer, and a shielding body provided between the second semiconductor layer and the third semiconductor layer.
(2)

An electronic apparatus according to another aspect of the present technology includes the optical detection device described above, an optical lens that forms an image of image light received from a subject on an imaging surface of the optical detection device, and a signal processing circuit that performs signal processing for a signal output from the optical detection device.

### BRIEF DESCRIPTION OF DRAWINGS

FIG. 1 is a chip layout diagram illustrating one configuration example of a solid-state imaging device according to a first embodiment of the present technology.

FIG. 2 is a block diagram illustrating one configuration example of the solid-state imaging device according to the first embodiment of the present technology.

FIG. 3 is an equivalent circuit diagram illustrating one configuration example of a sensor pixel and a pixel circuit of the solid-state imaging device according to the first embodiment of the present technology.

FIG. 4 is a vertical cross-sectional diagram schematically illustrating a vertical cross-sectional structure of the solid-state imaging device according to the first embodiment of the present technology.

FIG. 5A is a vertical cross-sectional diagram illustrating an enlarged part in FIG. 4.

FIG. 5B is a vertical cross-sectional diagram illustrating an enlarged part in FIG. 4.

FIG. 6A is a vertical cross-sectional diagram schematically illustrating a vertical cross-sectional structure of a shielding solid film mounted on the solid-state imaging device according to the first embodiment of the present technology.

FIG. 6B is a plan diagram schematically illustrating a planar pattern of the shielding solid film in FIG. 6A.

FIG. 7 is a diagram illustrating one example of circuit blocks of the solid-state imaging device according to the first embodiment of the present technology.

FIG. 8A is a vertical cross-sectional diagram schematically illustrating a vertical cross-sectional structure according to a modification of the first embodiment.

FIG. 8B is a plan diagram schematically illustrating a planar pattern of the modification of the first embodiment.

FIG. 9 is a vertical cross-sectional diagram schematically illustrating a vertical cross-sectional structure of a solid-state imaging device according to a second embodiment of the present technology.

FIG. 10 is a vertical cross-sectional diagram illustrating an enlarged part in FIG. 9.

FIG. 11A is a vertical cross-sectional diagram schematically illustrating a vertical cross-sectional structure of a shielding structure mounted on the solid-state imaging device according to the second embodiment of the present technology.

FIG. 11B is a plan diagram schematically illustrating a planar pattern of the shielding structure in FIG. 11A.

FIG. 12A is a vertical cross-sectional diagram schematically illustrating a vertical cross-sectional structure of a shielding structure mounted on a solid-state imaging device according to a third embodiment of the present technology.

FIG. 12B is a plan diagram schematically illustrating a planar pattern of the shielding structure in FIG. 11A.

FIG. 13 is a plan diagram schematically illustrating a planar pattern of a modification of the third embodiment.

FIG. 14A is a vertical cross-sectional diagram schematically illustrating a vertical cross-sectional structure of a shielding structure mounted on a solid-state imaging device according to a fourth embodiment of the present technology.

FIG. 14B is a plan diagram schematically illustrating a planar pattern of the shielding structure in FIG. 14A.

FIG. 15 is a plan diagram schematically illustrating a planar pattern of a modification of the fourth embodiment.

FIG. 16A is a vertical cross-sectional diagram schematically illustrating a vertical cross-sectional structure of a shielding structure mounted on a solid-state imaging device according to a fifth embodiment of the present technology.

FIG. 16B is a plan diagram schematically illustrating a planar pattern of the shielding structure in FIG. 16A.

FIG. 17 is a plan diagram schematically illustrating a planar pattern of a modification of the fifth embodiment.

FIG. 18A is a vertical cross-sectional diagram schematically illustrating a vertical cross-sectional structure of a shielding structure mounted on a solid-state imaging device according to a sixth embodiment of the present technology.

FIG. 18B is a plan diagram schematically illustrating a planar pattern of the shielding structure in FIG. 18A.

FIG. 19A is a vertical cross-sectional diagram schematically illustrating a vertical cross-sectional structure of a shielding structure mounted on a solid-state imaging device according to a seventh embodiment of the present technology.

FIG. 19B is a plan diagram schematically illustrating a planar pattern of the shielding structure in FIG. 19A.

FIG. 20 is a plan diagram schematically illustrating a planar pattern of a modification of the seventh embodiment.

FIG. 21A is a vertical cross-sectional diagram schematically illustrating a vertical cross-sectional structure of a shielding structure mounted on a solid-state imaging device according to an eighth embodiment of the present technology.

FIG. 21B is a plan diagram schematically illustrating a planar pattern of the shielding structure in FIG. 21A.

FIG. 22 is a plan diagram schematically illustrating a planar pattern of a modification of the eighth embodiment.

FIG. 23A is a vertical cross-sectional diagram schematically illustrating a vertical cross-sectional structure of a shielding structure mounted on a solid-state imaging device according to a ninth embodiment of the present technology.

FIG. 23B is a plan diagram schematically illustrating a planar pattern of the shielding structure in FIG. 23A.

FIG. 24 is a plan diagram schematically illustrating a planar pattern of a modification of the ninth embodiment.

FIG. 25 is a diagram illustrating a schematic configuration of an electronic apparatus according to a tenth embodiment of the present technology.

FIG. 26 is a block diagram depicting an example of schematic configuration of a vehicle control system.

FIG. 27 is a diagram of assistance in explaining an example of installation positions of an outside-vehicle information detecting section and an imaging section.

FIG. 28 is a view depicting an example of a schematic configuration of an endoscopic surgery system.

FIG. 29 is a block diagram depicting an example of a functional configuration of a camera head and a camera control unit (CCU).

### DESCRIPTION OF EMBODIMENTS

Embodiments according to the present technology will be hereinafter described in detail with reference to the drawings.

Note that identical or similar parts included in the drawings referred to in the following description will be given identical or similar reference signs. However, it should be taken into account that the drawings are only schematic figures which may include relations between thicknesses and planar sizes, ratios of thicknesses of respective layers, and other conditions different from actual ones. Accordingly, specific thicknesses and sizes should be determined in consideration of the following description.

Moreover, needless to say, size relations and ratios included in some of the drawings may be different from those of the other drawings. Furthermore, advantageous effects to be offered are not limited to those described in the present description only by way of example, and other advantageous effects may be additionally offered.

In addition, the following embodiments are presented only as examples of devices and methods for embodying the technical concept of the present technology, and specific configurations described below are not required to be adopted. Accordingly, the technical concept of the present technology may be modified in various manners within the technical scope defined in the claims.

Moreover, definitions of directions, such as an up-down direction, included in the following description are definitions provided only for convenience of explanation, and therefore do not restrict the technical concept of the present technology. For example, needless to say, an up-down direction of a target is switched to a left-right direction for observation of the target rotated through 90 degrees, or is vertically inverted for observation of the target rotated through 180 degrees.

In addition, among three directions perpendicular to each other within a space, it is assumed in the following embodiments that a first direction and a second direction perpendicular to each other in the same plane are an X direction and a Y direction, respectively, and that a third direction perpendicular to each of the first direction and the second direction is a Z direction. Besides, a thickness direction of each of semiconductor layers described below corresponds to the Z direction in the description of the following embodiments.

Moreover, in the description of the following embodiments, the Z direction corresponds to “one direction” of the present technology.

Furthermore, in the following embodiments, a thickness of each of the semiconductor layers corresponds to a separation distance between a first surface portion and a second surface portion located at positions opposite to each other in the Z direction, while each of the thickness directions of the semiconductor layers corresponds to a direction of the thickness of the corresponding semiconductor layer.

In addition, in the following embodiments, a planar view refers to a view of the semiconductor layers viewed in the Z direction (one direction). A cross-sectional view refers to a view of a cross section taken in the Z direction (one direction) and viewed in a direction perpendicular to this cross section (Z direction).

### First Embodiment

Described in a first embodiment herein will be an example of the present technology applied to an optical detection device which is a solid-state imaging device constituting a back-illuminated CMOS (Complementary Metal Oxide Semiconductor) image sensor.

Moreover, described in the first embodiment herein will be a shielding solid film functioning as a shielding body for shielding an electromagnetic field. The shielding solid film corresponds to one specific example of a “shielding body” according to the present technology.

### Overall Configuration of Solid-State Imaging Device

First, an overall configuration of a solid-state imaging device 1A will be touched upon.

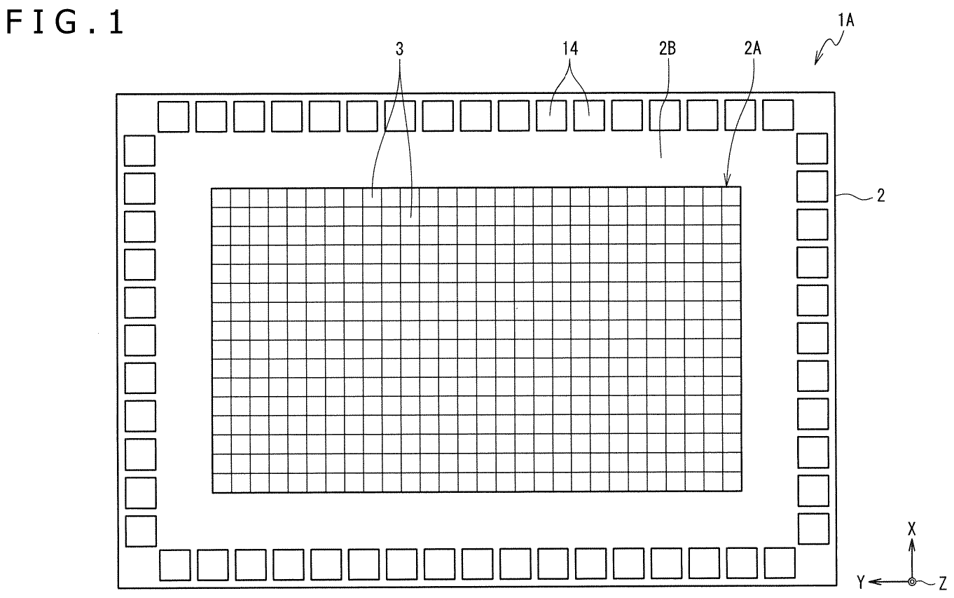

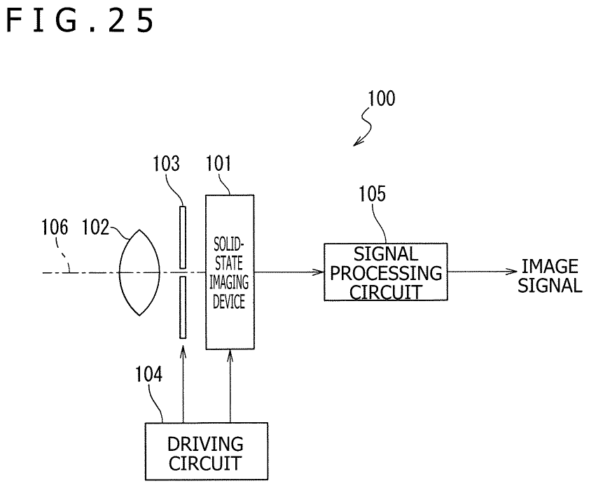

As illustrated in FIG. 1, the solid-state imaging device 1A according to the first embodiment of the present technology chiefly includes a semiconductor chip 2 which has a square two-dimensional planar shape in a planar view. Specifically, the solid-state imaging device 1A is mounted on the semiconductor chip 2, and therefore the semiconductor chip 2 can be considered as the solid-state imaging device 1A. As illustrated in FIG. 25, the solid-state imaging device 1A (101) introduces image light (incident light 106) received from a subject via an optical lens 102, converts a light quantity of the incident light 106 forming an image on an imaging surface into an electric signal for each pixel, and outputs the electric signal as a pixel signal.

As illustrated in FIG. 1, the semiconductor chip 2 on which the solid-state imaging device 1A is mounted includes, in a two-dimensional plane containing the X direction and the Y direction perpendicular to each other, a sensor pixel array section 2A having a square shape and provided at a central portion, and a peripheral section 2B provided outside the foregoing sensor pixel array section 2A and surrounding the sensor pixel array section 2A. The semiconductor chip 2 is formed in a manufacturing process as a small division of a semiconductor wafer including first to third semiconductor layers 20, 50, and 80 described below, and divided for each chip forming region. Accordingly, the solid-state imaging device 1A described hereinafter has a substantially similar configuration even in a wafer state before the semiconductor wafer is divided into small pieces. In other words, the present technology is applicable to both the semiconductor chip state and the semiconductor wafer state.

For example, the sensor pixel array section 2A is a light receiving surface which receives light collected by the optical lens (optical system) 102 illustrated in FIG. 25. In addition, a plurality of sensor pixels 3 are arranged in the sensor pixel array section 2A in a matrix shape in the two-dimensional plane containing the X direction and the Y direction. In other words, the sensor pixels 3 are repeatedly arranged in each of the X direction and the Y direction perpendicular to each other within the two-dimensional plane.

As illustrated in FIG. 1, a plurality of bonding pads 14 are disposed in the peripheral section 2B. For example, the plurality of bonding pads 14 are arrayed along each of four sides of the two-dimensional plane of the semiconductor chip 2. Each of the plurality of bonding pads 14 functions as an input/output terminal which electrically connects the semiconductor chip 2 to an external device.

### Logic Circuit

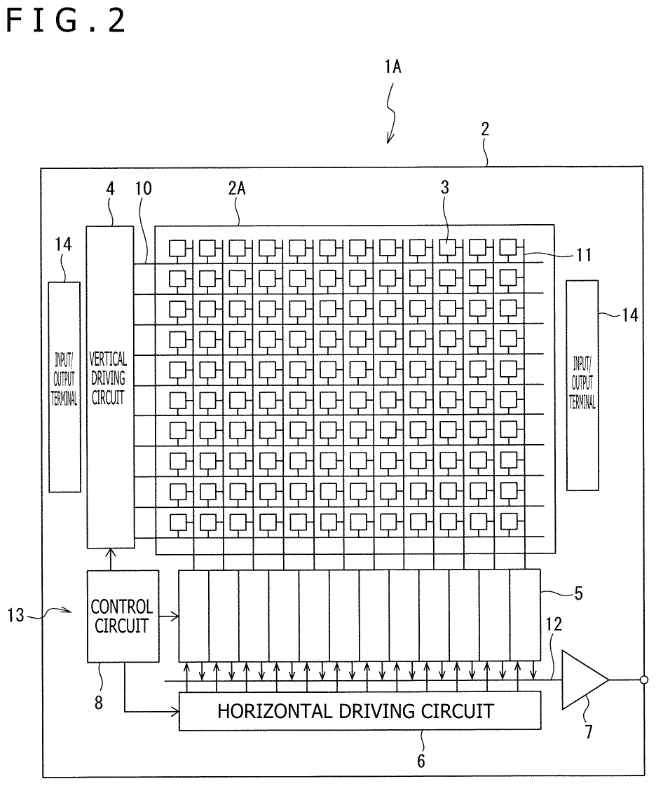

The semiconductor chip 2 includes a logic circuit 13 illustrated in FIG. 2. As illustrated in FIG. 2, the logic circuit 13 includes a vertical driving circuit 4, column signal processing circuits 5, a horizontal driving circuit 6, an output circuit 7, a control circuit 8, and others. The logic circuit 13 includes a CMOS (Complementary MOS) circuit which has an n-channel conductivity-type MOSFET (Metal Oxide Semiconductor Field Effect transistor) and a p-channel conductivity-type MOSFET as field effect transistors, for example.

The vertical driving circuit 4 includes a shift register, for example. The vertical driving circuit 4 sequentially selects a desired pixel drive line 10, and supplies pulses for driving the sensor pixels 3 to the selected pixel drive line 10 to drive the respective sensors 3 for each row. Specifically, the vertical driving circuit 4 selectively and sequentially scans the respective sensor pixels 3 of the sensor pixel array section 2A in the vertical direction for each row, and supplies, to the column signal processing circuits 5 via vertical signal lines 11, pixel signals each received from the sensor pixel 3 as a signal corresponding to signal charge generated by a photoelectric conversion portion (photoelectric conversion element) of the corresponding sensor pixel 3 on the basis of a light reception quantity.

For example, the column signal processing circuits 5 are arranged with one-to-one correspondence with the columns of the sensor pixels 3, and perform signal processing, such as noise removal, for signals output from the sensor pixels 3 in one row for each of the pixel columns. For example, each of the column signal processing circuits 5 performs signal processing, such as CDS (Correlated Double Sampling) and AD (Analog Digital) conversion, to remove fixed pattern noise peculiar to the pixels.

The horizontal driving circuit 6 includes a shift register, for example. The horizontal driving circuit 6 sequentially selects the respective column signal processing circuits 5 by sequentially outputting horizontal scanning pulses to the column signal processing circuits 5, and causes each of the column signal processing circuits 5 to output processed pixel signals to a horizontal signal line 12.

The output circuit 7 performs signal processing for the pixel signals sequentially supplied from the respective column signal processing circuits 5 via the horizontal signal line 12, and outputs the processed pixel signals. For example, this signal processing may include buffering, black level adjustment, column variation correction, various types of digital signal processing, and the like.

The control circuit 8 generates clock signals and control signals as operation references for the vertical driving circuit 4, the column signal processing circuits 5, the horizontal driving circuit 6, and the like on the basis of vertical synchronized signals, horizontal synchronized signals, and master clock signals. Thereafter, the control circuit 8 outputs the generated clock signals and control signals to the vertical driving circuit 4, the column signal processing circuits 5, the horizontal driving circuit 6, and the like.

### Circuit Configuration of Sensor Pixel

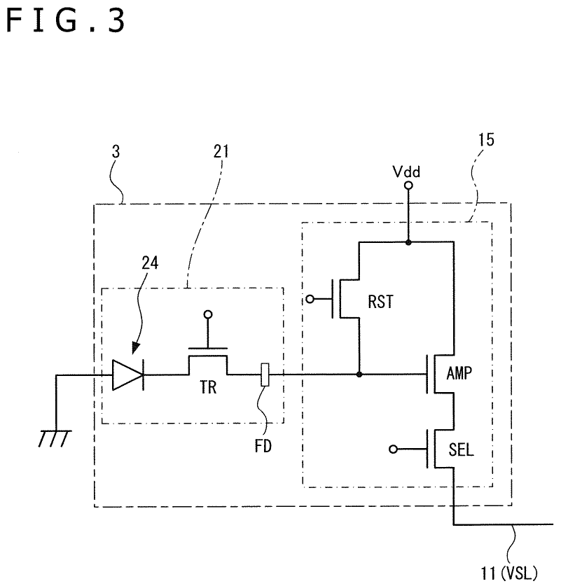

As illustrated in FIG. 3, each of a plurality of the sensor pixels 3 includes a photoelectric conversion region 21 and a pixel circuit (read circuit) 15. The photoelectric conversion region 21 includes a photoelectric conversion portion 24, a transfer transistor TR functioning as a pixel transistor, and a floating diffusion region FD functioning as a charge retention portion. The pixel circuit 15 is electrically connected to the floating diffusion region FD of the photoelectric conversion region 21.

The first embodiment presented herein by way of example has such a circuit configuration where the one pixel circuit 15 is allocated to the one sensor pixel 3. However, this configuration of the first embodiment is not required to be adopted. For example, such a circuit configuration is adoptable where the one pixel circuit 15 is shared by a plurality of the sensor pixels 3. Specifically, such a circuit configuration is adoptable where the one pixel circuit 15 is shared by one sensor pixel group (photoelectric conversion group) which is one unit constituted by the four sensor pixels 3 with 2×2 arrangement where the two pixels 3 are arranged for each of the X direction and the Y direction. Furthermore, such a circuit configuration is adoptable where the one pixel circuit 15 is shared by one sensor pixel group (photoelectric conversion group) which is one unit constituted by the two sensor pixels 3. In addition, such a circuit configuration is adoptable where the one pixel circuit 15 is shared by one sensor pixel group (photoelectric conversion group) which is one unit constituted by the four or more sensor pixels 3.

The photoelectric conversion portion 24 illustrated in FIG. 3 includes a pn junction type photodiode (PD), for example, and generates signal charge corresponding to a received light quantity. The photoelectric conversion portion 24 is configured such that the cathode side is electrically connected to a source region of the transfer transistor TR, and that the anode side is electrically connected to a reference potential line (e.g., ground).

The transfer transistor TR illustrated in FIG. 3 transfers signal charge photoelectrically converted by the photoelectric conversion portion 24 to the floating diffusion region FD. The source region of the transfer transistor RT is electrically connected to the cathode side of the photoelectric conversion portion 24, while a drain region of the transfer transistor TR is electrically connected to the floating diffusion region FD. In addition, a gate electrode of the transfer transistor TR is electrically connected to a transfer transistor drive line of the pixel drive lines 10 (see FIG. 2).

The floating diffusion region FD illustrated in FIG. 3 temporarily retains (accumulates) the signal charge transferred from the photoelectric conversion region 24 via the transfer transistor TR.

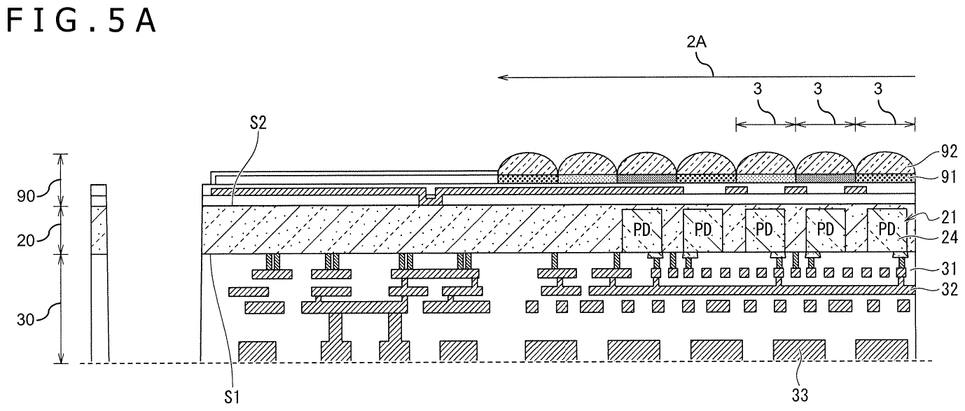

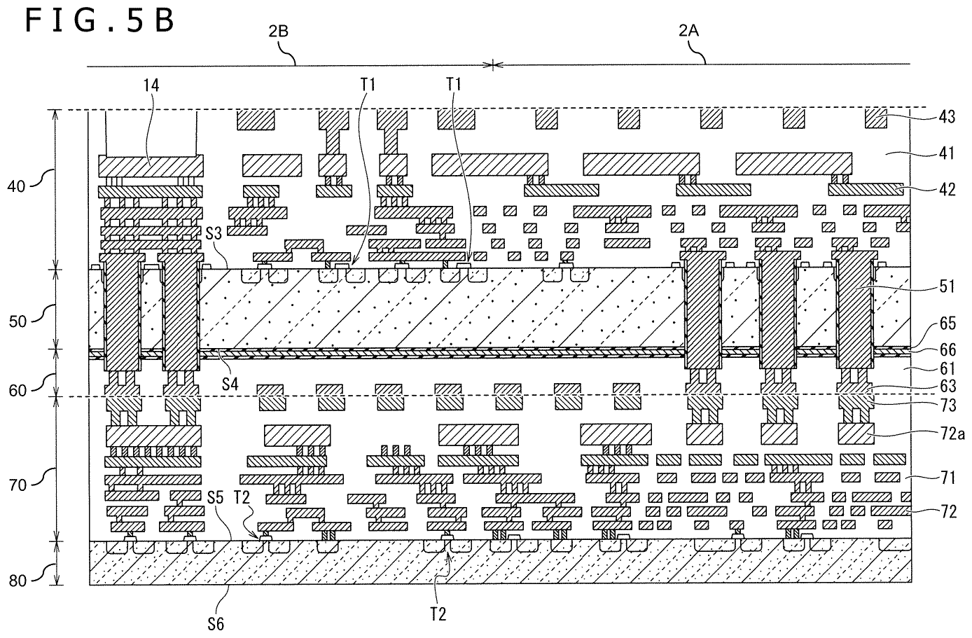

The photoelectric conversion region 21 including the photoelectric conversion portion 24, the transfer transistor TR, and the floating diffusion region FD is mounted in the first Semiconductor layer 20 illustrated in FIG. 5 for each of the sensor pixels 3.

The pixel circuit 15 illustrated in FIG. 3 reads the signal charge retained in the floating diffusion region FD, and outputs a pixel signal corresponding to the read signal charge. For example, the pixel circuit 15 includes, though not limited to the following, an amplification transistor AMP, a selection transistor SEL, and a reset transistor RST as pixel transistors. For example, as field effect transistors, each of these pixel transistors (AMP, SEL, RST) and the transfer transistor TR described above includes a MOSFET which has a gate insulation film including a silicon oxide (SiO₂) film, a gate electrode, and a pair of main electrode regions functioning as a source region and a drain region. Alternatively, each of the transistors may be a MISFET (Metal Insulator Semiconductor FET) which includes, as a gate insulation film, a silicon nitride (Si₃N₄) film, or a laminated film including a lamination of a silicon nitride film and a silicon oxide film or the like.

As illustrated in FIG. 3, the amplification transistor AMP is configured such that a source region is electrically connected to a drain region of the selection transistor SEL, and that a drain region is electrically connected to a power source line Vdd and a drain region of the reset transistor RST. In addition, a gate electrode of the amplification transistor AMP is electrically connected to the floating diffusion region FD and a source region of the reset transistor RST.

As illustrated in FIG. 3, the selection transistor SEL is configured such that a source region is electrically connected to the vertical signal line 11 (VSL), and that the drain region is electrically connected to the source region of the amplification transistor AMP. In addition, a gate electrode of the selection transistor SEL is electrically connected to a selection transistor drive line of the pixel drive lines 10 illustrated in FIG. 2.

As illustrated in FIG. 3, the reset transistor RST is configured such that a source region is electrically connected to the floating diffusion region FD and the gate electrode of the amplification transistor AMP, and that the drain region is electrically connected to the power source line Vdd and the drain region of the amplification transistor AMP. In addition, a gate electrode of the reset transistor RST is electrically connected to a reset transistor drive line of the pixel drive lines 10 illustrated in FIG. 2.

The transfer transistor TR illustrated in FIG. 3 transfers signal charge generated by the photoelectric conversion portion 24 to the floating diffusion region FD when the transfer transistor TRG is brought into an on-state.

The reset transistor RST illustrated in FIG. 3 resets a potential (signal charge) of the floating diffusion region FD to a potential of the power source line Vdd when the reset transistor RST is brought into an on-state. The selection transistor SEL controls output timing of pixel signals received from the pixel circuit 15.

The amplification transistor AMP illustrated in FIG. 3 generates, as a pixel signal, a signal indicating a voltage corresponding to a level of the signal charge retained in the floating diffusion region FD. The amplification transistor AMP constitutes a source-follower type amplifier, and outputs a pixel signal indicating a voltage corresponding to a level of the signal charge generated by the photoelectric conversion portion 24. When the selection transistor SEL is brought into an on-state, the amplification transistor AMP amplifies a potential of the floating diffusion region FD, and outputs a voltage corresponding to this potential to the column signal processing circuit 5 via the vertical signal line 11 (VSL).

Explained with reference to FIG. 3 herein, signal charge generated by the photoelectric conversion portion 24 of the sensor pixel 3 is retained (accumulated) in the floating diffusion region FD via the transfer transistor TR of the sensor pixel 3 during operation of the solid-state imaging device 1A according to the first embodiment herein. Thereafter, the signal charge retained in the floating diffusion region FD is read by the pixel circuit 15, and applied to the gate electrode of the amplification transistor AMP of the pixel circuit 15. A horizontal line selection control signal is given from a vertical shift register to the gate electrode of the selection transistor SEL of the pixel circuit 15. Thereafter, the selection transistor SEL becomes conductive in response to the selection control signal set to a high (H) level, and causes current which corresponds to the potential of the floating diffusion region FD after amplification by the amplification transistor AMP to flow in the vertical signal line 11. Moreover, the reset transistor RST becomes conductive in response to a reset control signal set to a high (H) level and applied to the gate electrode of the reset transistor RST of the pixel circuit 15, and resets the signal charge accumulated in the floating diffusion region FD.

### Different Pixel Circuit

Note that the selection transistor SEL may be eliminated as necessary. In a configuration not including the selection transistor SEL, the source region of the amplification transistor AMP is electrically connected to the vertical signal line 11 (VSL).

Moreover, a switching transistor may be provided between the reset transistor RST, and the floating diffusion region FD and the gate electrode of the amplification transistor AMP. The switching transistor controls charge retention by the floating diffusion region FD, and adjusts a voltage multiplication factor according to the potential amplified by the amplification transistor AMP.

In addition, the switching transistor is used for switching conversion efficiency. Generally, pixel signals are low during imaging at a dark place. If FD capacitance C (floating diffusion capacitance C) of the charge retention portion (floating diffusion region FD) is high at the time of charge-voltage conversion based on Q=CV, a voltage V lowers at the time of conversion into voltage by the amplification transistor AMP. Meanwhile, pixel signals are high at a bright place. Accordingly, unless the FD capacitance C of the charge retention portion is high, charge of the photoelectric conversion portion 24 (photodiode PD) is difficult to receive by the charge retention portion. Moreover, the FD capacitance C of the charge retention portion needs to be high so as to avoid an excessive increase in the voltage V (i.e., so as to reduce the voltage V) at the time of conversion into voltage by the amplification transistor AMP. In consideration of these circumstances, the gate capacitance increases by the capacitance of the switching transistor when the switching transistor is turned on. Accordingly, the overall FD capacitance C increases. Meanwhile, when the switching transistor is turned off, the overall FD capacitance C decreases. As apparent from above, the FD capacitance C is variable and conversion efficiency is hence switchable according to on-off switching of the switching transistor.

### Specific Configuration of Solid-State Imaging Device

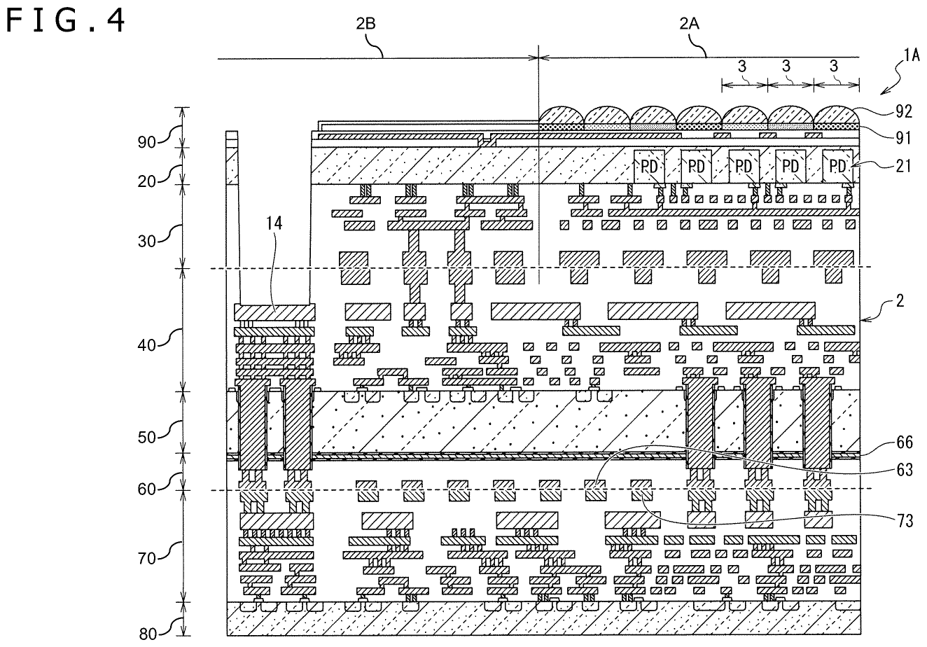

A specific configuration of the solid-state imaging device 1A will next be described with reference to FIGS. 4, 5A, and 5B.

### Laminated Structure of Solid-State Imaging Device

As illustrated in FIGS. 4, 5A, and 5B, the solid-state imaging device 1A (semiconductor chip 2) has a laminated structure which includes a light collection layer 90, the first semiconductor layer 20, a first wiring layer 30, a second wiring layer 40, the second semiconductor layer 50, a third wiring layer 60, a fourth wiring layer 70, and the third semiconductor layer 80 laminated in this order. Note herein that the first semiconductor layer 20, the second semiconductor layer 50, and the third semiconductor layer 80 correspond to one specific example of a “first semiconductor layer,” a “second semiconductor layer,” and a “third semiconductor layer” of the present technology, respectively. In addition, the third wiring layer 60 and the fourth wiring layer 70 correspond to one specific example of a “first wiring layer” and a “second wiring layer” of the present technology, respectively.

The first semiconductor layer 20 corresponding to the “first semiconductor layer” of the present technology has a first surface S1 and a second surface S2 located at positions opposite to each other in a thickness direction of the first semiconductor layer 20 (Z direction) (see FIG. 5A). In addition, the first semiconductor layer 20 includes the photoelectric conversion region 21 described below (see FIG. 5A).

The light collection layer 90 is provided on the second surface S2 side of the first semiconductor layer 20. In addition, for example, the light collection layer 90 has, though not limited to the following, a laminated structure where a color filter 91 and an on-chip lens 92 are laminated in this order from the second surface S2 side of the first semiconductor layer 20.

The first wiring layer 30 is provided on the first surface S1 side of the first semiconductor layer 20, and overlapped with the first surface S1 of the first semiconductor layer 20.

The second wiring layer 40 is provided on the side opposite to the first semiconductor layer 20 side of the first wiring layer 30, and overlapped with a surface of the first wiring layer 30 on the first semiconductor layer 20 side.

The second semiconductor layer 50 corresponding to the “second semiconductor layer” of the present technology has a third surface S3 and a fourth surface S4 located at positions opposite to each other in a thickness direction of the second semiconductor layer 50 (Z direction) (see FIG. 5B). In addition, the second semiconductor layer 50 is provided on the side opposite to the first wiring layer 30 side of the second wiring layer 40, and overlapped with a surface of the second wiring layer 40 on the side opposite to the first wiring layer 30 side.

The third wiring layer 60 corresponding to the “first wiring layer” of the present technology is provided on the side opposite to the second wiring layer 40 side of the second semiconductor layer 50, and overlapped with the fourth surface S4 of the second semiconductor layer 50.

The fourth wiring layer 70 corresponding to the “second wiring layer” of the present technology is provided on the side opposite to the second semiconductor layer 50 side of the third wiring layer 60, and overlapped with a surface of the third wiring layer 60 on the side opposite to the second semiconductor layer 50 side.

The third semiconductor layer 80 corresponding to the “third semiconductor layer” of the present technology has a fifth surface S5 and a sixth surface S6 located at positions opposite to each other in a thickness direction of the third semiconductor layer 80. In addition, the third semiconductor layer 80 is provided on the side opposite to the third wiring layer 60 side of the fourth wiring layer 70, and overlapped with a surface of the fourth wiring layer 70 on the side opposite to the third wiring layer 60 side.

Note herein that the first surface S1 of the first semiconductor layer 20 will be also referred to as an element forming surface or a main surface, and that the second surface S2 of the first semiconductor layer 20 will be also referred to as a light entrance surface or a rear surface. Moreover, the third surface S3 of the second semiconductor layer 50 will be also referred to as an element forming surface or a main surface, and the fourth surface S4 of the second semiconductor layer 50 will be also referred to as a rear surface. Furthermore, the fifth surface S5 of the third semiconductor layer 80 will be also referred to as an element forming surface or a main surface, and a surface on the side opposite to the fifth surface S5 will be also referred to as a rear surface.

In addition, the first semiconductor layer 20 and the second semiconductor layer 50 are joined to each other with interposition of the first wiring layer 30 and the second wiring layer 40 by F2F (Face to Face), i.e., such that the respective element forming surfaces face each other. Besides, the second semiconductor layer 50 and the third semiconductor layer 80 are joined to each other with interposition of the third wiring layer 60 and the fourth wiring layer 70 by B2F (Back to Face), i.e., such that the rear surface and the element forming surface face each other.

### First Semiconductor Layer

The first semiconductor layer 20 includes a semiconductor substrate. For example, the first semiconductor layer 20 includes a p-type monocrystal silicon substrate corresponding to a first conductivity type. The photoelectric conversion region 21 is formed in a region included in the first semiconductor layer 20 and overlapping with the sensor pixel array section 2A in a plan view, and is provided for each of the sensor pixels 3. While not illustrated in the figure, the photoelectric conversion region 21 is sectioned by a division region formed in the first semiconductor layer 20. Note that the number of the sensor pixels 3 is not limited to the number illustrated in FIG. 4.

While not illustrated in the figure, the photoelectric conversion region 21 includes a p-type well region and an n-type semiconductor region (photoelectric conversion portion) as a region corresponding to a second conductivity type and embedded inside the foregoing well region, for example. Photoelectric conversion elements PD illustrated in FIG. 3 are formed in the photoelectric conversion region 21 including the well region and the photoelectric conversion portion of the first semiconductor layer 20. In addition, the photoelectric conversion region 21 contains, though not limited to the following, a charge retention portion (charge accumulation portion) including an n-type semiconductor region, and the transfer transistor TR, for example.

### First Wiring Layer

The first wiring layer 30 includes an insulation film 31, wiring 32, junction pads (junction metal pads) 33, and contact electrodes (vias). As illustrated in the figure, the wiring 32 and the junction pads 33 are laminated with interposition of the insulation film 31. The junction pads 33 face a surface of the first wiring layer 30 on the side opposite to the first semiconductor layer 20 side. The junction pads 33 are provided in an uppermost layer of the first wiring layer 30 on the side opposite to the first semiconductor layer 20 side, and electrically connected to the wiring 32 in a lower layer via the contact electrodes. Each of the wiring 32 and the junction pads 33 may be made of, though not limited to the following, copper, for example, and formed by damascene method.

### Second Wiring Layer

The second wiring layer 40 includes an insulation film 41, wiring 42, junction pads (junction metal pads) 43, and contact electrodes (vias). As illustrated in the figure, the wiring 42 and the junction pads 43 are laminated with interposition of the insulation film 41. The junction pads 43 face a surface of the second wiring layer 40 on the side opposite to the second semiconductor layer 50 side. The junction pads 43 are provided in an uppermost layer of the second wiring layer 40 on the side opposite to the second semiconductor layer 50, and electrically connected to the wiring 42 in a lower layer via the contact electrodes. In addition, the junction pads 43 are joined to the corresponding junction pads 33 in the first wiring layer 30.

Each of the wiring 42 and the junction pads 43 may be made of, though not limited to the following, copper, for example, and formed by damascene method.

### Second Semiconductor Layer

The second semiconductor layer 50 includes, though not limited to the following, a p-type monocrystal silicon substrate, for example. A plurality of transistors T1 are provided in the second semiconductor layer 50. For example, the transistors T1 are pixel transistors constituting the pixel circuit (read circuit) 15 illustrated in FIG. 3, and transistors constituting the logic circuit 13 illustrated in FIG. 2.

### Third Wiring Layer

As illustrated in FIG. 5B, the third wiring layer 60 includes an insulation film 61, wiring 62, and junction pads (junction metal pads) 63. The wiring 62 and the junction pads 63 are laminated with interposition of the insulation film 61 as illustrated in the figure. The junction pads 63 face a surface of the third wiring layer 60 on the side opposite to the second semiconductor layer 50 side. Each of the wiring 62 and the junction pads 63 may be made of, though not limited to the following, copper, for example, and formed by damascene method.

According to the first embodiment presented herein, each of the junction pads 63 corresponds to one specific example of a “first junction pad” of the present technology, and the third wiring layer 60 corresponds to one specific example of a “first wiring layer” of the present technology.

### Fourth Wiring Layer

As illustrated in FIG. 5B, the fourth wiring layer 70 includes an insulation film 71, wiring 72 and wiring 72a, junction pads (junction metal pads) 73, and contact electrodes. The wiring 72 and the junction pads 73 are laminated with interposition of the insulation film 71 as illustrated in the figure. The junction pads 73 face a surface of the fourth wiring layer 70 on the side opposite to the third semiconductor layer 80 side. The junction pads 73 are provided in an uppermost layer of the fourth wiring layer 70 on the second semiconductor layer 50 side, and electrically connected to the wiring 72a in a lower layer via the contact electrodes. Each of the wiring 72 and the junction pads 73 may be made of, though not limited to the following, copper, for example, and formed by damascene method. Meanwhile, the wiring 72a includes an aluminum film, for example, unlike the wiring 72 located in a layer lower than the foregoing wiring 72a.

### Third Semiconductor Layer

For example, the third semiconductor layer 80 includes a p-type monocrystal silicon substrate. A plurality of transistors T2 are provided in the third semiconductor layer 80. For example, the transistors T2 are transistors constituting the logic circuit 13 illustrated in FIG. 2.

### Through Contact Electrode

As illustrated in FIG. 5B, the wiring 42 in the second wiring layer 40 and the junction pads 63 in the third wiring layer 60 are electrically connected to each other via through contact electrodes 51 which penetrate the second semiconductor layer 50 in the thickness direction thereof (Z direction). While not illustrated in the figure, each of the through contact electrodes 51 penetrates a through hole in the second semiconductor layer 50, and is electrically insulated within the through hole from the second semiconductor layer 50 with interposition of an insulation film. It is preferable that the through contact electrodes 51 penetrating the second semiconductor layer 50 be made of a material having a linear thermal expansion coefficient close to that of the second semiconductor layer 50. Because the second semiconductor layer 50 includes monocrystal silicon in this embodiment, the through contact electrodes 51 are made of polycrystal silicon to which an impurity for reducing resistance has been introduced.

### Shielding Solid Film

As illustrated in FIG. 5B, a shielding solid film 66 functioning as a shielding body is provided on the fourth surface S4 side of the second semiconductor layer 50. In other words, the solid-state imaging device 1A according to the first embodiment herein includes the shielding solid film 66 as a shielding body between the second semiconductor layer 50 and the third semiconductor layer 80. The shielding solid film 66 is fixed to the fourth surface S4 of the second semiconductor layer 50 with interposition of a fixed charge film 65. In addition, the shielding solid film 66 reduces an electromagnetic field propagating from one of the second semiconductor layer 50 and the third semiconductor layer 80 to the other.

For example, the fixed charge film 65 includes a dielectric film which generates negative fixed charge. For example, this dielectric film may be made of hafnium oxide (HfO₂) having a high dielectric constant. The fixed charge film 65 thus provided can induce holes (h⁺) at a surface portion of the second semiconductor layer 50 on the fourth surface S4 side, and achieve sufficient pinning at this interface portion. Alternatively, this dielectric film may be made of other materials such as zirconium oxide (ZrO₂) and tantalum oxide (Ta₂O₅).

The shielding solid film 66 is electrically connected to wiring to which a potential is applied. In addition, the shielding solid film 66 has a potential fixed to the potential applied to the wiring. For example, this potential is a power source potential supplied from a power source generation circuit. For example, this power source potential is a first reference potential having 0 V, a second reference potential as a positive potential higher than the foregoing first reference potential, a third reference potential as a negative potential lower than the foregoing first reference potential, or the like. According to this embodiment, the first reference potential having 0 V is supplied to the shielding solid film 66, for example. The potential applied to the shielding solid film 66 is maintained during operation of the solid-state imaging device 1A.

It is preferable that the shielding solid film 66 be made of a material appropriate for shielding an electromagnetic field, such as band noise and hot carrier light. For example, the shielding solid film 66 may be made of high-melting-point metal such as tantalum (Ta), titanium (Ti), and tungsten (W), nitrides of these, or metal such as coper (Cu) and aluminum (Al).

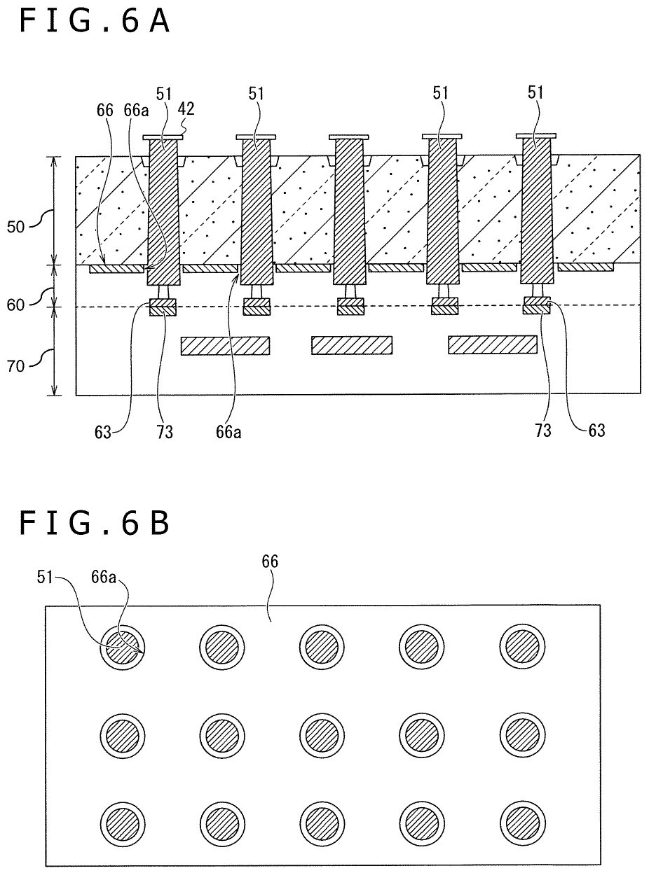

As illustrated in FIG. 5B, the shielding solid film 66 is provided on the fourth surface S4 side of the second semiconductor layer 50 throughout the sensor pixel array section 2A and the peripheral section 2B in a planar view, and has a plate shape expanding two-dimensionally. In addition, as illustrated in FIGS. 6A and 6B, the shielding solid film 66 has openings 66a through which the through contact electrodes 51 penetrate. Specifically, each of the through contact electrodes 51 penetrates the through hole in the second semiconductor layer 50 and the opening 66a in the shielding solid film 66, and achieves electrical connection between the wiring 42 formed in the second wiring layer 40 on the third surface S3 side of the second semiconductor layer 50, and the junction pad 63 formed in the third wiring layer 60 on the fourth surface S4 side of the second semiconductor layer 50.

The openings 66a can be formed by patterning the shielding solid film 66 with use of a known photolithography technology or a known dry etching technology. In addition, the shielding solid film 66 may be selectively provided through patterning in alignment with a region desired to be shielded. Accordingly, while the shielding solid film 66 is provided on the fourth surface S4 side of the second semiconductor layer 50 through the sensor pixel array section 2A and the peripheral section 2B as illustrated in FIG. 5B in this embodiment, the shielding solid film 66 may be selectively provided in a region desired to be shielded, such as the peripheral section 2B.

### Main Advantageous Effects of Embodiment

Main advantageous effects of the first embodiment presented above will next be described.

The transistors T1 constituting the pixel circuit 15 and the logic circuit 13 are provided in the second semiconductor layer 50. Meanwhile, the transistors T2 constituting the logic circuit 13 are provided in the third semiconductor layer 80 as well. Meanwhile, according to this embodiment, the shielding solid film 66 is provided between the third semiconductor layer 80 in the lower stage and the second semiconductor layer 50 in the middle stage. In this case, the shielding solid film 66 is provided between the transistors T2 in the third semiconductor layer 80 in the lower stage and the transistors T1 in the second semiconductor layer 50 in the middle stage. Accordingly, propagation of band noise generated during operation of the transistors T2 to the transistors T1 can be cut off by the shielding solid film 66. Conversely, propagation of band noise generated during operation of the transistors T1 to the transistors T2 can be also cut off by the shielding solid film 66. Accordingly, this configuration can reduce band noise generated during operation of either the transistors T2 in the third semiconductor layer 80 in the lower stage or the transistors T1 in the second semiconductor layer 50 in the middle stage and propagating from the transistors generating this band noise to the other transistors, and thus can reduce crosstalk which influences operation of the other transistors.

Moreover, the pixel transistors included in the pixel circuit 15 are provided in the second semiconductor layer 50 different from the first semiconductor layer 20 where the photoelectric conversion portion 24, the transfer transistor TR, and the charge retention portion (FD) are provided. Accordingly, the degree of freedom in arrangement of the pixel transistors (AMP, SEL, RST) included in the pixel circuit 15 can be raised, and integration and noise immunity can be further enhanced compared to a case where the photoelectric conversion portion 24, the transfer transistor TR, the charge retention portion (FD), and the pixel transistors are provided in the same semiconductor layer.

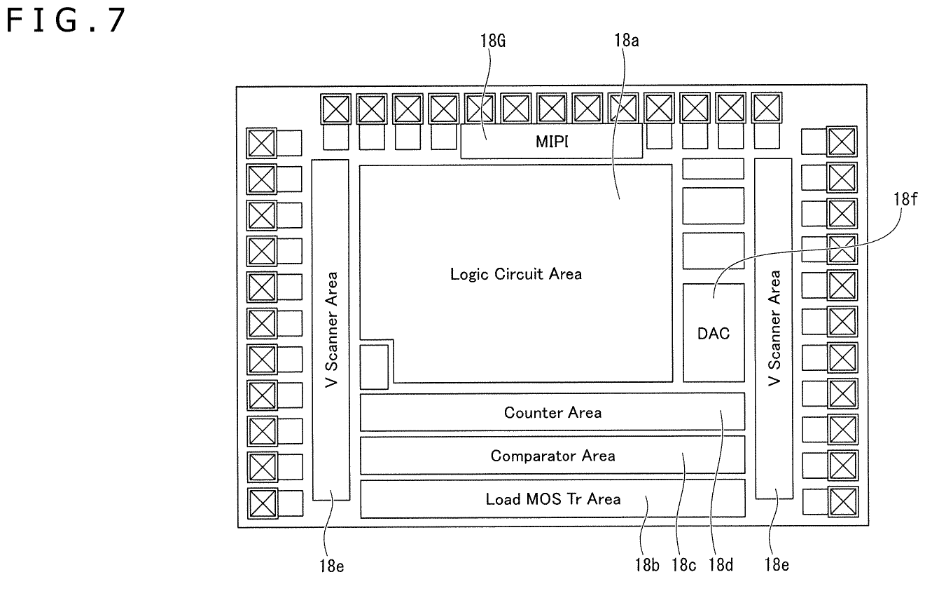

FIG. 7 is a diagram illustrating one example of circuit blocks.

The solid-state imaging device 1A according to the first embodiment herein includes circuit blocks illustrated in FIG. 7, for example. In the circuit blocks in FIG. 7, a circuit block 18a includes a logic operation circuit, a circuit block 18b includes a load MOS transistor circuit, a circuit block 18c includes a comparator circuit, and a circuit block 18d includes a counter circuit. Moreover, a circuit block 18e includes a scanner circuit, a circuit block 18f includes a D/C converter, and a circuit block 18G includes a mobile processor interface circuit.

Each of these circuit blocks includes the transistors T1 in the second semiconductor layer 50, and the transistors T2 in the third semiconductor layer 80. In addition, among these circuit blocks, each of the circuit blocks 18a, 18b, 18c, 18f, and 18G operates at high speed, and therefore is likely to become a noise source. Accordingly, if such a configuration is adopted which selectively arranges the shielding solid film 66 in such a manner as to overlap with the circuit blocks each likely to become a noise source in a planar view, crosstalk between the third semiconductor layer 80 in the lower stage and the second semiconductor layer 50 in the middle stage can be reduced. In this case, the shielding solid film 66 selectively overlaps with the circuit blocks desired to be shielded in a planar view.

As described above, the logic circuit 13 illustrated in FIG. 2 includes a CMOS circuit. This CMOS circuit requires a countermeasure for preventing latch up. However, transistors emit hot carrier light during operation. This hot carrier light may become one of factors causing latch up. Meanwhile, the shielding solid film 66 provided between the transistors T2 in the third semiconductor layer 80 in the lower stage and the transistors T1 in the second semiconductor layer 50 in the middle stage can cut off hot carrier light emitted from the transistors T2 and T1. Accordingly, reduction of latch up caused by hot carrier light is achievable.

Note that the shielding solid film 66 may be provided directly on the fourth surface S4 of the second semiconductor layer 50. In this case, a reference potential is usually supplied to the second semiconductor layer 50. Accordingly, the shielding solid film 66 also has a potential fixed to the reference potential of the second semiconductor layer 50.

Moreover, all the pixel transistors included in the pixel circuit 15 in FIG. 3 may be provided in the first semiconductor layer 20.

Furthermore, pixel transistors included in the pixel circuit 15 and both illustrated and not illustrated in FIG. 3 may be appropriately divided into a group arranged in the first semiconductor layer 20 and a group arranged in the second semiconductor layer 50.

Besides, a signal processing circuit, a driving circuit, a memory circuit, and the like may be arranged in at least any one of the first semiconductor layer 20, the second semiconductor layer 50, and the third semiconductor layer 80 in any manner.

### Modification of First Embodiment

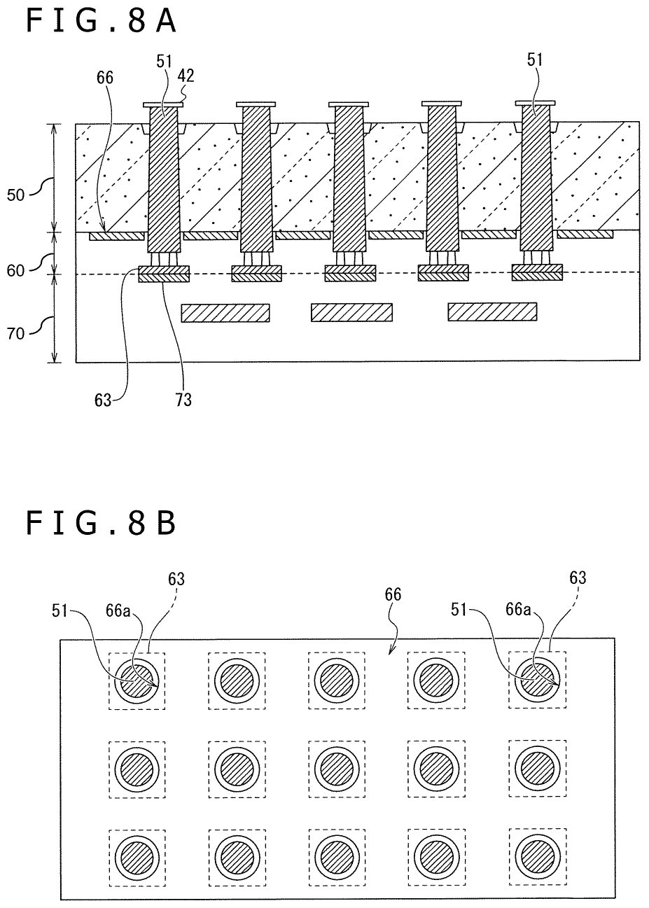

According to the first embodiment described above, clearances are produced between the shielding solid film 66 and the through contact electrodes 51 according to separation between the shielding solid film 66 and the through contact electrodes 51. Accordingly, there is a possibility that an electromagnetic field, such as band noise and hot carrier light, passes through these clearances. For solving this problem, at least either the junction pads 63 or the junction pads 73 may be each shaped to have a planar size sufficient for overlapping with the whole of the opening 66a of the shielding solid film 66 in a planar view to prevent passage of the electromagnetic field as illustrated in FIGS. 8A and 8B. In FIGS. 8A and 8B, both the junction pads 63 and the junction pads 73 are each shaped to have a planar size sufficient for overlapping with the whole of the opening 66a of the shielding solid film 66 in a planar view.

### Second Embodiment

Described in a second embodiment herein will be a shielding structure including first junction pads and second junction pads and functioning as a shielding body for cutting off an electromagnetic field.

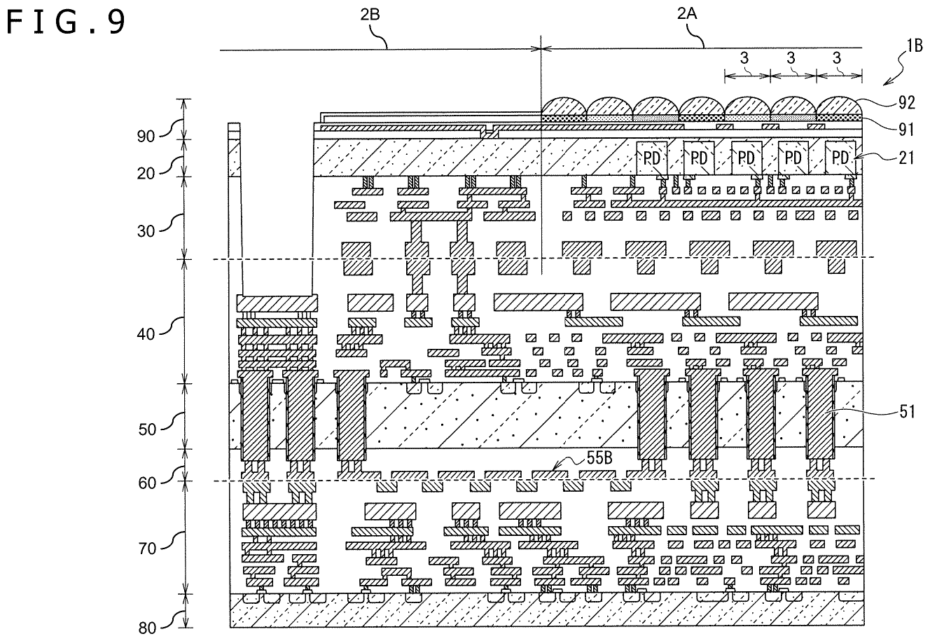

FIG. 9 is a vertical cross-sectional diagram schematically illustrating a vertical cross-sectional structure of a solid-state imaging device 1B according to the second embodiment of the present technology.

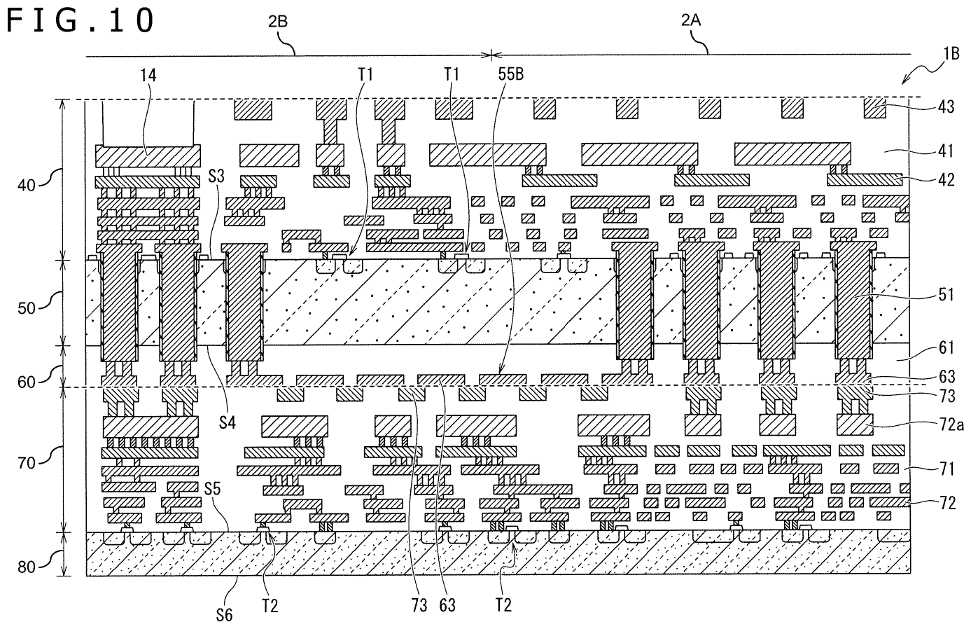

FIG. 10 is a vertical cross-sectional diagram illustrating an enlarged part in FIG. 9.

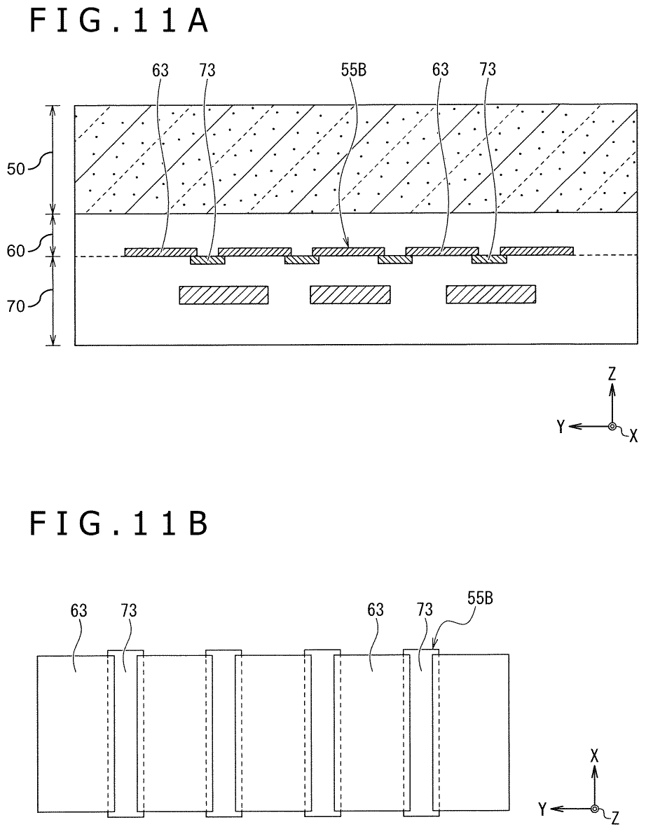

FIG. 11A is a vertical cross-sectional diagram illustrating a simplified vertical cross-sectional structure of a shielding structure illustrated in FIG. 9.

FIG. 11B is a plan diagram illustrating a simplified planar pattern of the shielding structure illustrated in FIG. 9.

As illustrated in FIGS. 9 and 10, the solid-state imaging device 1B according to the second embodiment herein basically has configurations similar to the configurations of the solid-state imaging device 1A according to the first embodiment described above but is different in the following configurations.

Specifically, as illustrated in FIGS. 9 and 10, the solid-state imaging device 1B according to the second embodiment herein includes a shielding structure 55B instead of the shielding solid film 66 illustrated in FIG. 5B according to the first embodiment described above. Other configurations are substantially similar to the corresponding configurations of the first embodiment described above. The shielding structure 55B corresponds to one specific example of the “shielding body” according to the present technology.

As illustrated in FIGS. 9 and 10, the solid-state imaging device 1B according to the second embodiment herein includes the shielding structure 55B between the second semiconductor layer 50 and the third semiconductor layer 80 as a shielding body.

As illustrated in FIGS. 11A and 11B, the shielding structure 55B includes junction pads 63 provided between the second semiconductor layer 50 and the third semiconductor layer 80 and linearly extending in the X direction (first direction) in a planar view, and junction pads 73 joined to the foregoing junction pads 63 on the third semiconductor layer 80 side of the foregoing junction pads 63 and linearly extending in the X direction (first direction) in the planar view.

As illustrated in FIGS. 11A and 11B, the shielding structure 55B has the junction pads 63 and the junction pads 73 repeatedly arranged at positions relatively offset from each other in the Y direction (second direction) crossing the X direction in the planar view. In addition, some of the junction pad 63 and some of the junction pad 73 in each adjoining pair are overlapped with and joined to each other in the planar view. Accordingly, the shielding structure 55B constitutes a shielding plate which combines the junction pads 63 and the junction pads 73 and two-dimensionally expands in the planar view. Similarly to the shielding solid film 66 described above, the shielding structure 55B in the second embodiment herein is electrically connected to wiring to which a potential is applied, and has a potential fixed to the potential applied to this wiring. In addition, the shielding structure 55B also reduces an electromagnetic field propagating from one of the second semiconductor layer 50 and the third semiconductor layer 80 to the other.

The shielding structure 55B according to the second embodiment herein constitutes the shielding plate which combines the junction pads 63 and the junction pads 73 and two-dimensionally expands in the planar view. The shielding structure 55B configured as above can reduce noise generated during operation of either the transistors T2 in the third semiconductor layer 80 in the lower stage or the transistors T1 in the second semiconductor layer 50 in the middle stage and propagating from the transistors generating this band noise to the other transistors, and therefore can reduce crosstalk which influences operation of the other transistors.

Accordingly, the solid-state imaging device 1B including the foregoing shielding structure 55B according to the second embodiment can also offer advantageous effects similar to those of the solid-state imaging device 1A of the first embodiment described above.

### Third Embodiment

Described in a third embodiment herein will be a shielding structure including first junction pads, second junction pads, and conductors penetrating the second semiconductor layer, and functioning as a shielding body for cutting off an electromagnetic field.

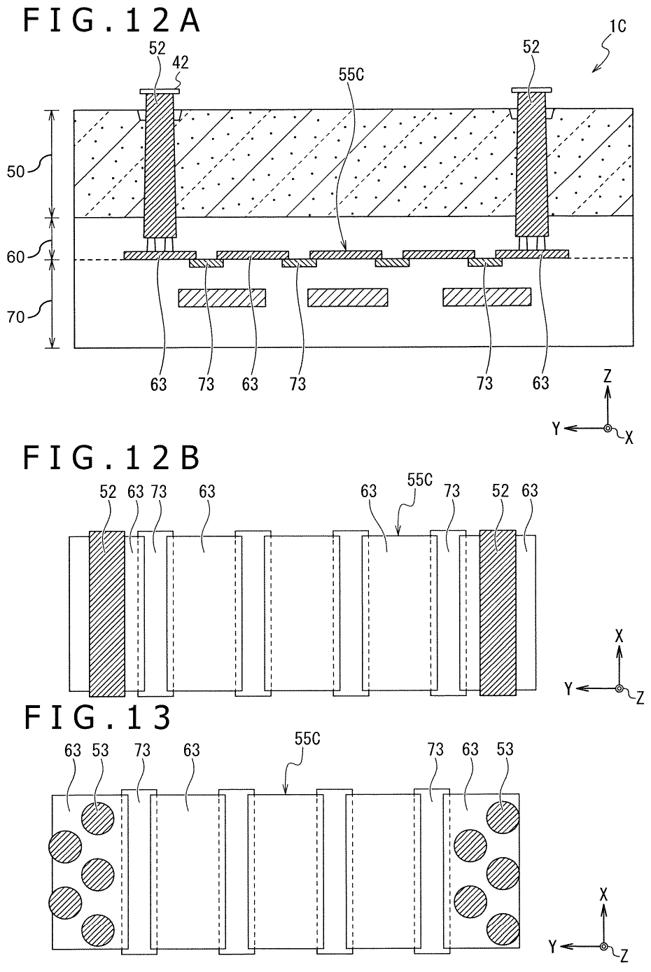

FIG. 12A is a vertical cross-sectional diagram illustrating a simplified vertical cross-sectional structure of a shielding structure mounted on a solid-state imaging device according to the third embodiment of the present technology.

FIG. 12B is a planar diagram illustrating a simplified planar pattern of the shielding structure in FIG. 12A.

A solid-state imaging device 1C according to the third embodiment herein includes a shielding structure 55C instead of the shielding structure 55B illustrated in FIG. 9 according to the second embodiment described above. Other configurations are substantially similar to the corresponding configurations of the first embodiment described above.

While not illustrated in the figures, the solid-state imaging device 1C according to the third embodiment herein includes the shielding structure 55C between the second semiconductor layer 50 and the third semiconductor layer 80 as a shielding body as can be understood with reference to FIG. 10 instead of the shielding structure 55B similarly to the second embodiment described above. The shielding structure 55C of the third embodiment herein corresponds to one specific example of the “shielding body” according to the present technology.

As illustrated in FIGS. 12A and 12B, the shielding structure 55C includes the junction pads 63 provided between the second semiconductor layer 50 and the third semiconductor layer 80 (see FIG. 10) and linearly extending in the X direction (first direction) in a planar view, and the junction pads 73 joined to the foregoing junction pads 63 on the third semiconductor layer 80 side of the foregoing junction pads 63 and linearly extending in the X direction (first direction) in the planar view. In addition, unlike the shielding structure 55B of the second embodiment described above, the shielding structure 55C further includes conductors 52 each of which penetrates in the thickness direction of the second semiconductor layer 50 (Z direction), overlaps with the junction pad 63 in the planar view, and linearly extends in the X direction. The conductors 52 thus provided can be formed by the Same step as the step for forming the through contact electrodes 51. The foregoing conductors 52 correspond to one specific example of a “conductor” of the present technology.

As illustrated in FIGS. 12A and 12B, the shielding structure 55C has the junction pads 63 and the junction pads 73 repeatedly arranged at positions relatively offset from each other in the Y direction (second direction) crossing the X direction in the planar view. In addition, some of the junction pad 63 and some of the junction pad 73 in each adjoining pair are overlapped with and joined to each other in the planar view. Accordingly, the shielding structure 55C also constitutes a shielding plate which combines the junction pads 63 and the junction pads 73 and two-dimensionally expands in the planar view. Similarly to the shielding solid film 66 described above, the shielding structure 55C in the third embodiment herein is electrically connected to wiring to which a potential is applied, and has a potential fixed to the potential applied to this wiring. In addition, the shielding structure 55C also reduces an electromagnetic field propagating from one of the second semiconductor layer 50 and the third semiconductor layer 80 to the other.

The conductors 52 are electrically connected to the corresponding junction pads 63 via contact electrodes. In addition, among a plurality of the junction pads 63 repeatedly arranged in the Y direction, the conductors 52 are disposed at, though not limited to the following, a position overlapping with the junction pad 63 arranged in the initial stage in the planar view, and a position overlapping with the junction pad 63 arranged in the final stage in the planar view.

The shielding structure 55C according to the third embodiment herein constitutes the shielding plate which combines the junction pads 63 and the junction pads 73 and two-dimensionally expands in the planar view. Accordingly, the shielding structure 55C can reduce noise generated during operation of either the transistors T2 in the third semiconductor layer 80 in the lower stage or the transistors T1 in the second semiconductor layer 50 in the middle stage and propagating from the transistors generating this band noise to the other transistors, and therefore can reduce crosstalk which influences operation of the other transistors.

Moreover, the shielding structure 55C of this embodiment includes the conductors 52 penetrating the second semiconductor layer 50. Accordingly, shielding efficiency improves in comparison with the shielding structure 55B of the second embodiment described above.

As a result, the solid-state imaging device 1C according to this embodiment can further reduce crosstalk.

### Modification of Third Embodiment

Described in the third embodiment has been the shielding structure 55C including the conductors 52 each extending in the X direction. However, the present technology is not limited to the configuration equipped with the conductors 52 extending in the X direction.

For example, as illustrated in FIG. 13, such a configuration is adoptable as a shielding body which includes conductors 53 which penetrate the second semiconductor layer 50 in the thickness direction (Z direction) similarly to the conductors 52, overlap with the junction pads 63 in a planar view, and are arranged as a plurality of conductors scattered in the X direction in a dotted shape, instead of the conductors 52 extending in the X direction. In this case, each of the conductors 53 may have a circular or square planar shape. In addition, this configuration can further improve shielding efficiency in a planar direction by arranging the conductors 53 in a staggered shape instead of a straight line. The conductors 53 thus configured can be formed by the same step as the step for forming the through contact electrodes 51. The foregoing conductors 53 correspond to one specific example of the “conductor” of the present technology.

### Fourth Embodiment

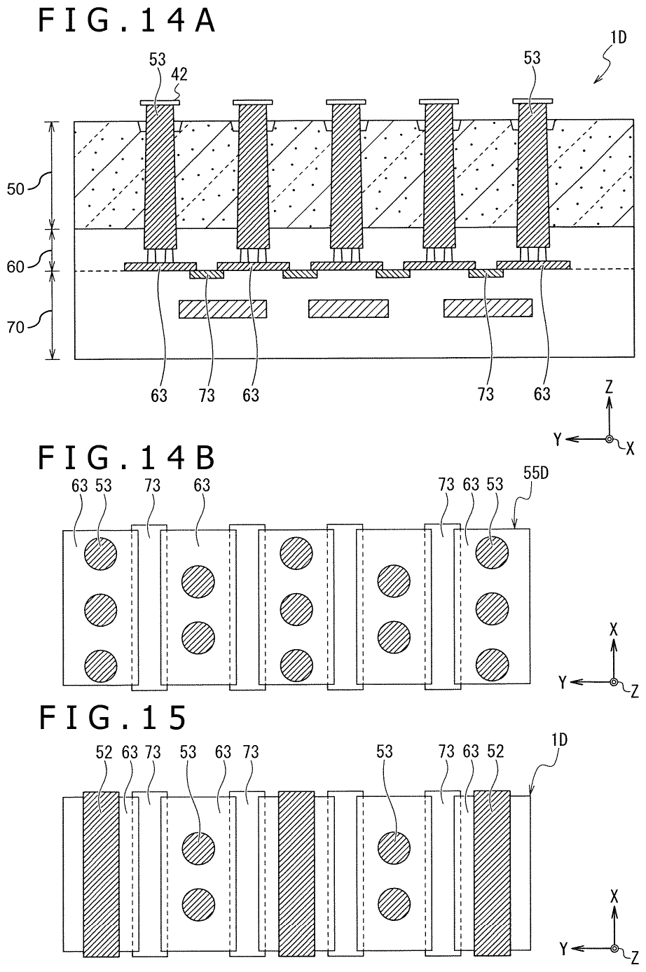

FIG. 14A is a vertical cross-sectional diagram illustrating a simplified vertical cross-sectional structure of a shielding structure mounted on a solid-state imaging device according to a fourth embodiment of the present technology.

FIG. 14B is a plan diagram illustrating a simplified planar pattern of the shielding structure illustrated in FIG. 14A.

A solid-state imaging device 1D according to the fourth embodiment herein includes a shielding structure 55D instead of the shielding structure 55B illustrated in FIGS. 11A and 11B according to the second embodiment described above. Other configurations are substantially similar to the corresponding configurations in the first embodiment described above.

Similarly to the second embodiment described above, the solid-state imaging device 1D according to the fourth embodiment herein includes the shielding structure 55D between the second semiconductor layer 50 and the third semiconductor layer 80 instead of the shielding structure 55B as can be understood with reference to FIG. 10. The shielding structure 55D in the fourth embodiment herein corresponds to one specific example of the “shielding body” of the present technology.

As illustrated in FIGS. 14A and 14B, the shielding structure 55D includes the junction pads 63 provided between the second semiconductor layer 50 and the third semiconductor layer 80 (see FIG. 10) and linearly extending in the X direction (first direction) in a planar view, and the junction pads 73 joined to the foregoing junction pads 63 on the third semiconductor layer 80 side of the foregoing junction pads 63 and linearly extending in the X direction (first direction) in the planar view. In addition, unlike the shielding structure 55B of the second embodiment described above, the shielding structure 55D further includes the conductors 53 which penetrate the second semiconductor layer 50 in the thickness direction (Z direction), overlap with the junction pads 63 in the planar view, and are arranged as a plurality of conductors scattered in the X direction in a dotted shape.

The shielding structure 55D has the junction pads 63 and the junction pads 73 repeatedly arranged at positions relatively offset from each other in the Y direction (second direction) crossing the X direction in the planar view. In addition, some of the junction pad 63 and some of the junction pad 73 in each adjoining pair are overlapped with and joined to each other in the planar view. Accordingly, the shielding structure 55D also constitutes a shielding plate which combines the junction pads 63 and the junction pads 73 and two-dimensionally expands in the planar view. Similarly to the shielding solid film 66 described above, the shielding structure 55D in the fourth embodiment herein is electrically connected to wiring to which a potential is applied, and has a potential fixed to the potential applied to this wiring. In addition, the shielding structure 55D also reduces an electromagnetic field propagating from one of the second semiconductor layer 50 and the third semiconductor layer 80 to the other.

The conductors 53 are electrically connected to the junction pads 63 via contact electrodes. In addition, the conductors 53 are arranged as, though not limited to the following, a plurality of conductors scattered in a dotted shape in the X direction for each of a plurality of the junction pads 63 repeatedly arranged in the Y direction.

The solid-state imaging device 1D according to the fourth embodiment herein also offers advantageous effects similar to those of the solid-state imaging device 1C of the third embodiment described above.

### Modification of Fourth Embodiment

Described in the fourth embodiment has been the conductors 53 arranged as a plurality of conductors scattered in the X direction to constitute conductors included in the shielding structure. However, the present technology is not limited to the configuration equipped with the conductors 53 arranged as a plurality of conductors scattered in the X direction.

For example, as illustrated in FIG. 15, the conductors 52 linearly extending in the X direction and the conductors 53 arranged as a plurality of conductors scatted in the X direction in a dotted shape may be combined. This configuration can also offer advantageous effects similar to those of the first embodiment described above. In this case, the conductors 52 correspond to one specific example of a “first conductor” of the present technology, while the conductors 53 correspond to one specific example of a “second conductor” of the present technology.

### Fifth Embodiment

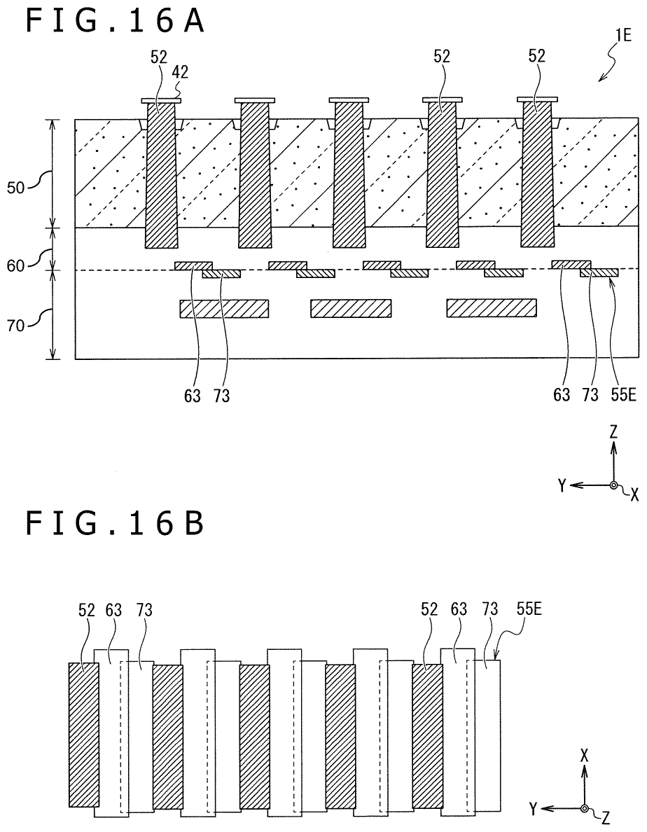

FIG. 16A is a vertical cross-sectional diagram illustrating one simplified configuration example of a shielding structure mounted on a solid-state imaging device according to a fifth embodiment of the present technology.

FIG. 16B is a plan diagram illustrating a simplified planar pattern of the shielding structure illustrated in FIG. 16A.

A solid-state imaging device 1E according to the fifth embodiment herein includes a shielding structure 55E instead of the shielding structure 55B illustrated in FIG. 10 according to the second embodiment described above. Other configurations are substantially similar to the corresponding configurations in the first embodiment described above.

While not illustrated in the figures, similarly to the second embodiment described above, the solid-state imaging device 1E according to the fifth embodiment herein includes the shielding structure 55E between the second semiconductor layer 50 and the third semiconductor layer 80 as a shielding body instead of the shielding structure 55B as can be understood with reference to FIG. 10. The shielding structure 55E corresponds to one specific example of the “shielding body” of the present technology.

As illustrated in FIGS. 16A and 16B, the shielding structure 55E includes the conductors 52 penetrating the second semiconductor layer 50 in the thickness direction (Z direction) and linearly extending in the X direction in a planar view, the junction pads 63 provided between the second semiconductor layer 50 and the third semiconductor layer 80 (see FIG. 10) and linearly extending in the X direction (first direction) in the planar view, and the junction pads 73 joined to the foregoing junction pads 63 on the third semiconductor layer 80 side of the foregoing junction pads 63 and linearly extending in the X direction (first direction) in the planar view.

The shielding structure 55E has the conductors 52, the junction pads 63, and the junction pads 73 repeatedly arranged at positions relatively offset from each other in the Y direction crossing the X direction in the planar view. Moreover, some of the junction pad 63 and some of the junction pad 73 in each adjoining pair are overlapped with and joined to each other in the planar view. Furthermore, overlapping with some of the junction pads 63 and 73 is made between each adjoining pair of the junction pads 63 and the junction pads 73 in the planar view. Accordingly, the shielding structure 55E constitutes a shielding plate which combines the conductors 52, the junction pads 63, and the junction pads 73 and two-dimensionally expands in the planar view. The conductors 52 are separated from each of the junction pads 63 and 73. Similarly to the shielding solid film 66 described above, the shielding structure 55E in the fifth embodiment herein is electrically connected to wiring to which a potential is applied, and has a potential fixed to the potential applied to this wiring. In addition, the shielding structure 55E also reduces an electromagnetic field propagating from one of the second semiconductor layer 50 and the third semiconductor layer 80 to the other.

The solid-state imaging device 1E according to the fifth embodiment herein also offers advantageous effects similar to those of the solid-state imaging device 1C of the third embodiment described above.

### Modification of Fifth Embodiment

Described in the fifth embodiment has been the shielding structure 55E including the conductors 52 each extending in the X direction. However, the present technology is not limited to the configuration equipped with the conductors 52 extending in the X direction.

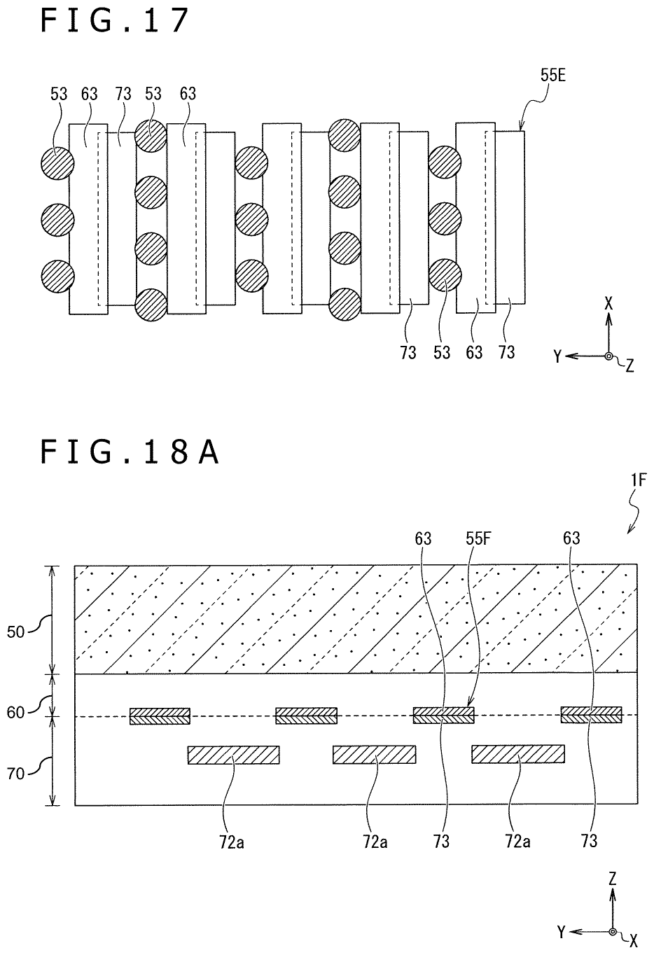

For example, as illustrated in FIG. 17, such a configuration is adoptable as a shielding structure which includes the conductors 53 arranged as a plurality of conductors scattered in the X direction in a dotted shape instead of the conductors 52 extending in the X direction.

### Sixth Embodiment

Described in a sixth embodiment herein will be a shielding structure including first and second junction pads and wiring as a shielding body for cutting off an electromagnetic field.

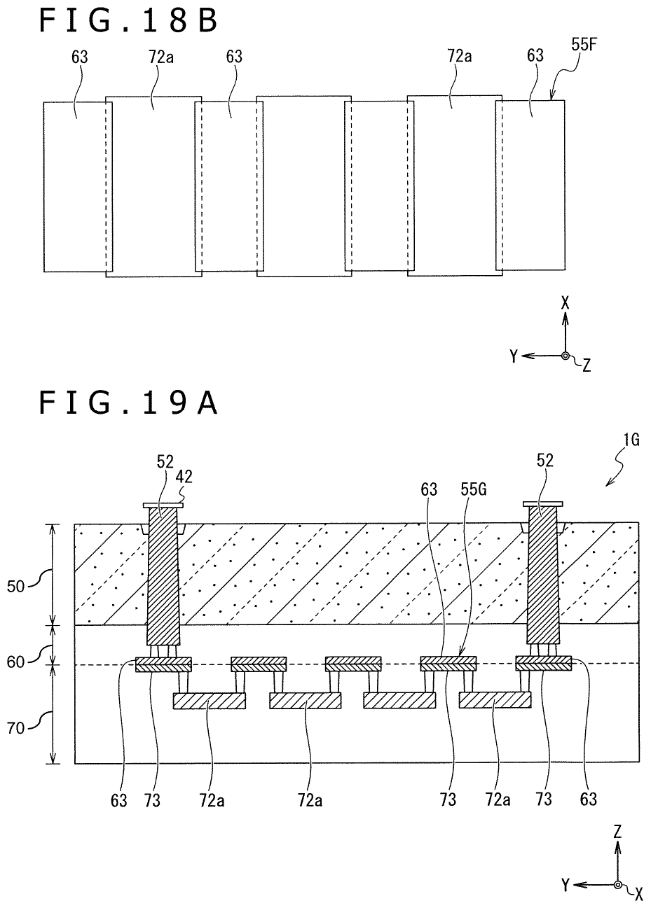

FIG. 18A is a vertical cross-sectional diagram illustrating a simplified vertical cross-sectional structure of a shielding structure mounted on a solid-state imaging device according to the sixth embodiment of the present technology.

FIG. 18B is a plan diagram illustrating a simplified planar pattern of the shielding structure illustrated in FIG. 18A.

A solid-state imaging device 1F according to the sixth embodiment herein includes a shielding structure 55F instead of the shielding structure 55B illustrated in FIG. 10 according to the second embodiment described above. Other configurations are substantially similar to the corresponding configurations in the first embodiment described above.

Similarly to the second embodiment described above, the solid-state imaging device 1F according to the sixth embodiment herein includes the shielding structure 55F between the second semiconductor layer 50 and the third semiconductor layer 80 instead of the shielding structure 55B as can be understood with reference to FIG. 10. The shielding structure 55F corresponds to one specific example of the “shielding body” of the present technology.

As illustrated in FIGS. 18A and 18B, the shielding structure 55F includes the junction pads 63 provided between the second semiconductor layer 50 and the third semiconductor layer 80 (see FIG. 10) and linearly extending in the X direction (first direction) in a planar view, and the junction pads 73 joined to the junction pads 63 on the third semiconductor layer 80 side of the foregoing junction pads 63 and linearly extending in the X direction in the planar view. Moreover, the shielding structure 55F further includes the wiring 72a provided on the third semiconductor layer 80 side of the junction pads 73 and linearly extending in the X direction in the planar view. The wiring 72a thus formed is provided in the fourth wiring layer 70, and on the third semiconductor layer 80 side with respect to the junction pads 73.

The shielding structure 55F has the junction pads 63 and 73 and the wiring 72a repeatedly arranged at positions relatively offset from each other in the Y direction (second direction) crossing the X direction in the planar view. Moreover, the junction pad 63 and the junction pad 73 in each adjoining pair are overlapped with and joined to each other in the planar view. Furthermore, the wiring 72a overlaps with some of the junction pads 63 and 73 between the junction pads 63 and 73 in the planar view. Accordingly, the shielding structure 55F constitutes a shielding plate which combines the junction pads 63 and 73 and the wiring 72a and two-dimensionally expands in the planar view. Similarly to the shielding solid film 66 described above, the shielding structure 55F in the sixth embodiment herein is electrically connected to wiring to which a potential is applied, and has a potential fixed to the potential applied to this wiring. In addition, the shielding structure 55F also reduces an electromagnetic field propagating from one of the second semiconductor layer 50 and the third semiconductor layer 80 to the other.

The solid-state imaging device 1F according to the sixth embodiment herein also offers advantageous effects similar to those of the solid-state imaging device 1B of the second embodiment described above.

### Seventh Embodiment

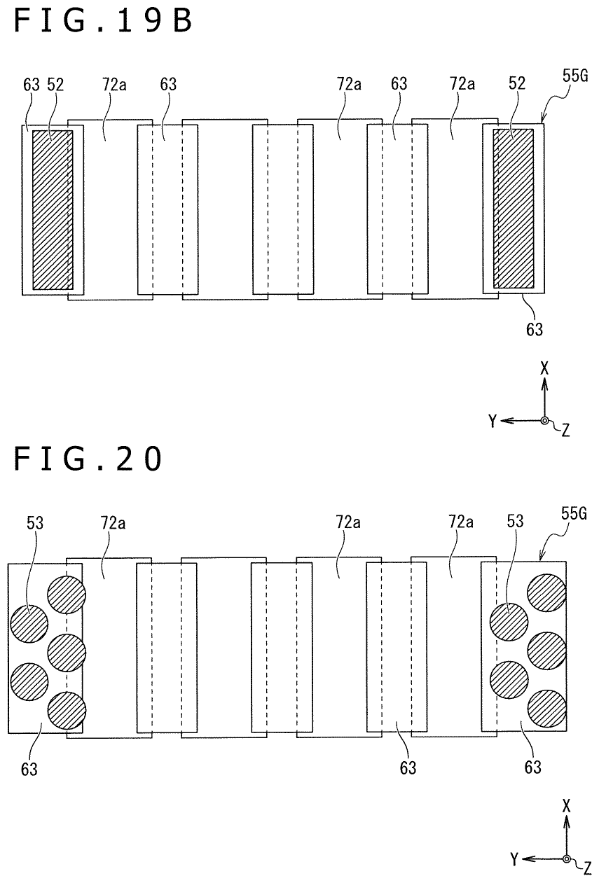

FIG. 19A is a vertical cross-sectional diagram illustrating a simplified vertical cross-sectional structure of a shielding structure mounted on a solid-state imaging device according to a seventh embodiment of the present technology.

FIG. 19B is a plan diagram illustrating a simplified planar pattern of the shielding structure illustrated in FIG. 19A.

A solid-state imaging device 1G according to the seventh embodiment herein includes a shielding structure 55G instead of the shielding structure 55B illustrated in FIG. 10 according to the second embodiment described above. Other configurations are substantially similar to the corresponding configurations in the first embodiment described above.

Similarly to the second embodiment described above, the solid-state imaging device 1G according to the seventh embodiment herein includes the shielding structure 55G between the second semiconductor layer 50 and the third semiconductor layer 80 instead of the shielding structure 55B as can be understood with reference to FIG. 10. The shielding structure 55G in the seventh embodiment herein corresponds to one specific example of the “shielding body” of the present technology.

As illustrated in FIGS. 19A and 19B, the shielding structure 55G has a configuration incorporating the conductors 52 into the shielding structure 55F of the sixth embodiment described above. Each of the conductors 52 is electrically connected to the junction pad 63 via a contact electrode. Moreover, among a plurality of the junction pads 63 repeatedly arranged in the Y direction, the conductors 52 are disposed at, though not limited to the following, a position overlapping with the junction pad 63 arranged in the initial stage in the planar view, and a position overlapping with the junction pad 63 arranged in the final stage in the planar view. Furthermore, the junction pads 73 are electrically connected to the wiring 72a in a lower layer via contact electrodes. Similarly to the shielding solid film 66 described above, the shielding structure 55G in the seventh embodiment herein is electrically connected to wiring to which a potential is applied, and has a potential fixed to the potential applied to this wiring. In addition, the shielding structure 55G configured as above also reduces an electromagnetic field propagating from one of the second semiconductor layer 50 and the third semiconductor layer 80 to the other.

The solid-state imaging device 1G according to the seventh embodiment herein also offers advantageous effects similar to those of the solid-state imaging device 1C of the third embodiment described above.

### Modification of Seventh Embodiment

Described in the seventh embodiment has been the shielding structure 55G including the conductors 52 each extending in the X direction. However, the present technology is not limited to the configuration equipped with the conductors 52 extending in the X direction.

For example, as illustrated in FIG. 20, such a configuration is adoptable as a shielding structure which includes the conductors 53 configured to penetrate the second semiconductor layer 50 in the thickness direction (Z direction) similarly to the conductors 52, overlap with the junction pads 63 in a planar view, and are arranged as a plurality of conductors scattered in the X direction in a dotted shape, instead of the conductors 52 extending in the X direction. In this case, each of the conductors 53 may have a circular or square planar shape. In addition, shielding efficiency in a planar direction in this configuration can be further raised by arranging the conductors 53 in a staggered shape instead of a straight line.

### Eighth Embodiment

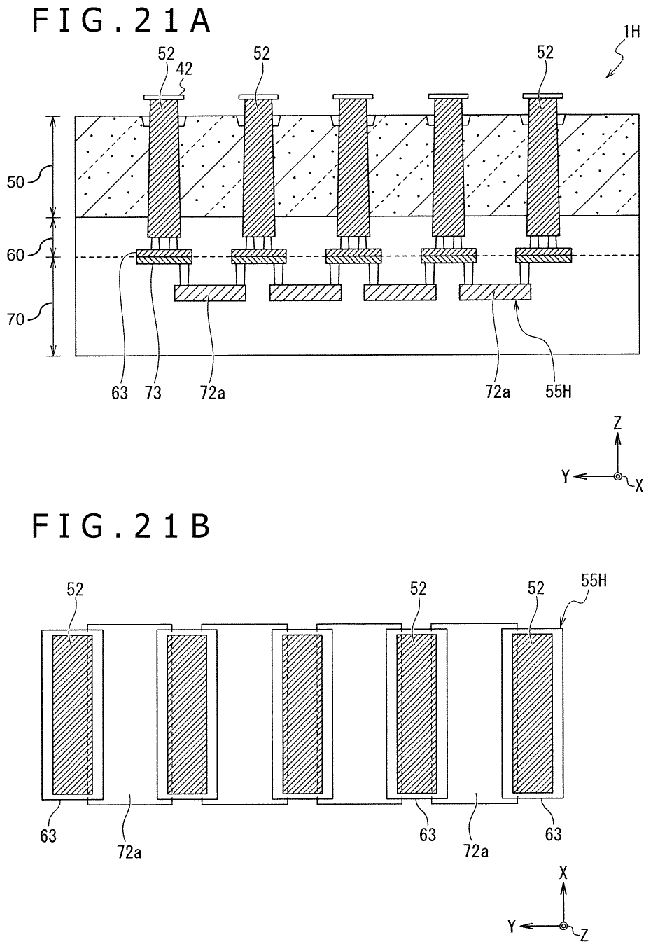

FIG. 21A is a vertical cross-sectional diagram illustrating a simplified vertical cross-sectional structure of a shielding structure mounted on a solid-state imaging device according to an eighth embodiment of the present technology.

FIG. 21B is a plan diagram illustrating a simplified planar pattern of the shielding structure illustrated in FIG. 21A.

A solid-state imaging device 1H according to the eighth embodiment herein includes a shielding structure 55H instead of the shielding structure 55B illustrated in FIG. 10 according to the second embodiment described above. Other configurations are substantially similar to the corresponding configurations in the first embodiment described above.

Similarly to the second embodiment described above, the solid-state imaging device 55H according to the eighth embodiment herein includes the shielding structure 55H between the second semiconductor layer 50 and the third semiconductor layer 80 instead of the shielding structure 55B as can be understood with reference to FIG. 10. The shielding structure 55H in the eighth embodiment herein corresponds to one specific example of the “shielding body” of the present technology.

As illustrated in FIGS. 21A and 22B, the shielding structure 55H basically has configurations substantially similar to the configurations of the shielding structure 55G of the seventh embodiment described above. The shielding structure 1H is different from the shielding structure 1G in that the conductor 52 is provided for each of the junction pads 63. Similarly to the shielding solid film 66 described above, the shielding structure 55H in the eighth embodiment herein is electrically connected to wiring to which a potential is applied, and has a potential fixed to the potential applied to this wiring. In addition, the shielding structure 55H configured as above also reduces an electromagnetic field propagating from one of the second semiconductor layer 50 and the third semiconductor layer 80 to the other.

The solid-state imaging device 1H according to the eighth embodiment herein also offers advantageous effects similar to those of the solid-state imaging device 1D of the fourth embodiment described above.

### Modification of Eighth Embodiment

Described in the eighth embodiment has been the shielding structure 55H including the conductors 52 each extending in the X direction. However, the present technology is not limited to the configuration equipped with the conductors 52 extending in the X direction.

For example, as illustrated in FIG. 22, such a configuration is adoptable as a shielding structure which includes conductors 53 configured to penetrate the second semiconductor layer 50 in the thickness direction (Z direction) similarly to the conductors 52, overlap with the junction pads 63 in a planar view, and are arranged as a plurality of conductors scattered in the X direction in a dotted shape, instead of the conductors 52 extending in the X direction. In this case, each of the conductors 53 may have a circular or square planar shape. In addition, the conductors 53 may be arranged in a staggered shape instead of the straight line adopted in this modification.

### Ninth Embodiment

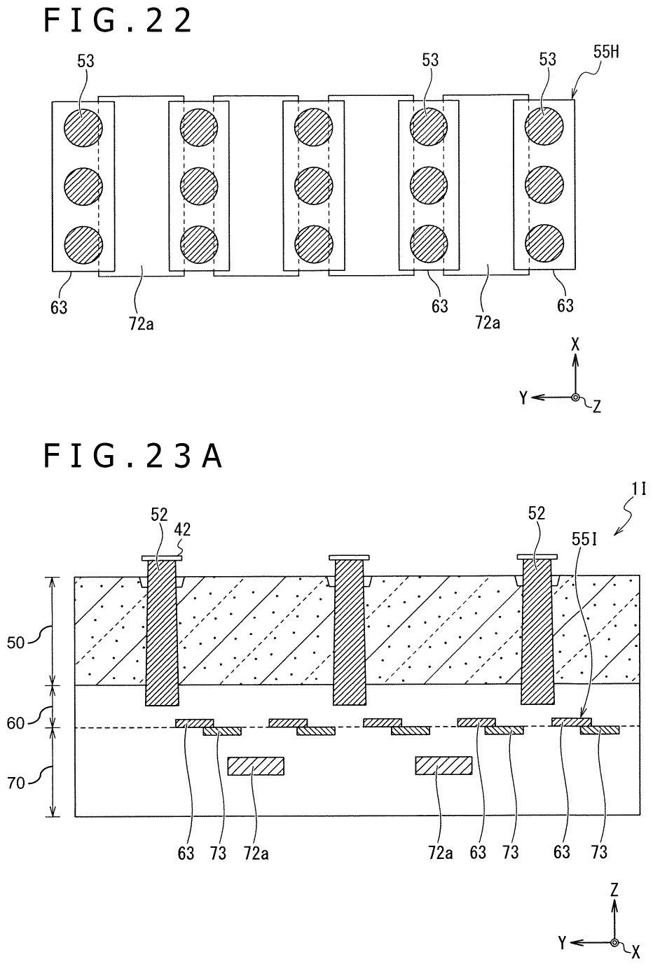

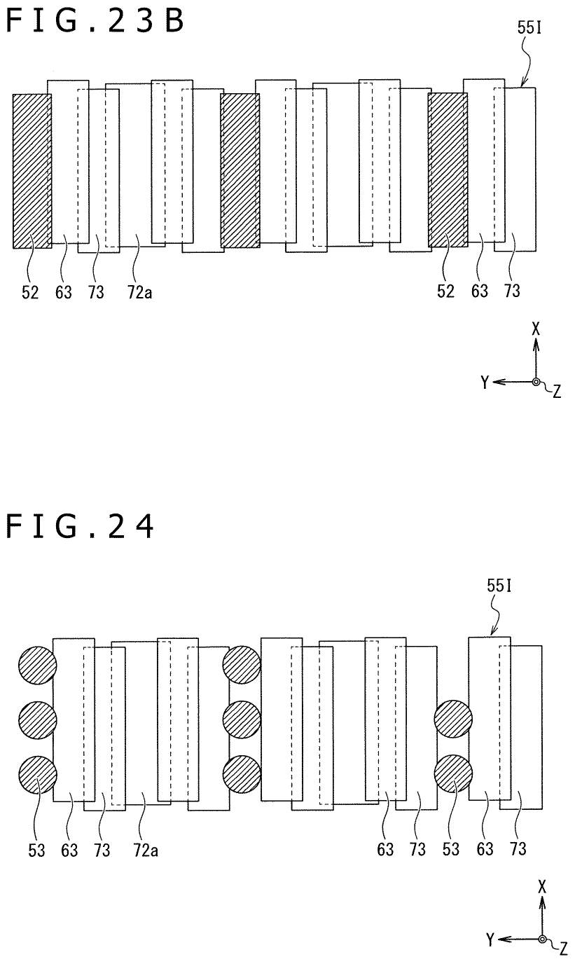

FIG. 23A is a vertical cross-sectional diagram illustrating a simplified vertical cross-sectional structure of a shielding structure mounted on a solid-state imaging device according to a ninth embodiment of the present technology.

FIG. 23B is a plan diagram illustrating a simplified planar pattern of the shielding structure illustrated in FIG. 23A.

A solid-state imaging device 1I according to the ninth embodiment herein includes a shielding structure 55I instead of the shielding structure 55B illustrated in FIG. 10 according to the second embodiment described above. Other configurations are substantially similar to the corresponding configurations in the first embodiment described above.

Similarly to the second embodiment described above, the solid-state imaging device 1I according to the ninth embodiment herein includes the shielding structure 55I between the second Semiconductor layer 50 and the third semiconductor layer 80 instead of the shielding structure 55B as can be understood with reference to FIG. 10. The shielding structure 55I in the ninth embodiment herein corresponds to one specific example of the “shielding body” of the present technology.

As illustrated in FIGS. 23A and 23B, the shielding structure 55I includes the conductors 52 penetrating the second semiconductor layer 50 in the thickness direction, the junction pads 63 provided between the second semiconductor layer 50 and the third semiconductor layer 80 (see FIG. 10) and linearly extending in the X direction in a planar view, the junction pads 73 joined to the junction pads 63 on the third semiconductor layer 80 side of the foregoing junction pads 63 and linearly extending in the X direction in the planar view, and the wiring 72a provided on the third semiconductor layer 80 side with respect to the junction pads 73 and linearly extending in the X direction in the planar view. In addition, the shielding structure 55I has the conductors 52, the junction pads 63, the junction pads 73, and the wiring 72a repeatedly arranged at positions relatively offset from each other in the Y direction crossing the X direction in the planar view.

Some of the junction pad 63 and some of the junction pad 73 in each adjoining pair are overlapped with and joined to each other in the planar view. The wiring 72a overlaps with some of the junction pads 63 and 73 between the adjoining junction pads 63 and 73 in the planar view. Each of the conductors 52 overlaps with some of the junction pads 63 and 73 between the adjoining junction pads 63 and 73 in the planar view. In addition, the wiring 72a and the conductors 52 are alternately arranged in the Y direction in the planar view. The shielding structure 55I thus configured also constitutes a shielding plate which combines the conductors 52, the junction pads 63, and the junction pads 73 and two-dimensionally expands in the planar view. Moreover, similarly to the shielding solid film 66 described above, the shielding structure 55I in the ninth embodiment herein is electrically connected to wiring to which a potential is applied, and has a potential fixed to the potential applied to this wiring. Furthermore, the shielding structure 55I configured as above also reduces an electromagnetic field propagating from one of the second semiconductor layer 50 and the third semiconductor layer 80 to the other.

Each of the conductors 52 and the wiring 72a is separated from each of the junction pads 63 and 73, and is not electrically connected to the junction pads 63 and 73 via a contact electrode.

The solid-state imaging device 1I according to the ninth embodiment herein also offers advantageous effects similar to those of the solid-state imaging device 1D of the fourth embodiment described above.

### Modification of Ninth Embodiment

Described in the ninth embodiment has been the shielding structure 55I including the conductors 52 each extending in the X direction. However, the present technology is not limited to the configuration equipped with the conductors 52 extending in the X direction.

For example, as illustrated in FIG. 24, such a configuration is adoptable as a shielding structure which includes the conductors 53 configured to penetrate the second semiconductor layer 50 in the thickness direction (Z direction) similarly to the conductors 52, overlap with the junction pads 63 in a planar view, and are arranged as a plurality of conductors scattered in the X direction in a dotted shape, instead of the conductors 52 extending in the X direction. In this case, each of the conductors 53 may have a circular or square planar shape. In addition, the conductors 53 may be arranged in a staggered shape instead of the straight line adopted in this modification.

### Tenth Embodiment

### 1. Example of Application to Electronic Apparatus

Described next will be an electronic apparatus 100 illustrated in FIG. 25 according to a tenth embodiment of the present technology. The electronic apparatus 100 includes the solid-state imaging device 101, the optical lens 102, a shutter device 103, a driving circuit 104, and a signal processing circuit 105. For example, the electronic apparatus 100 is, though not limited to the following, an electronic apparatus such as a camera. In addition, the electronic apparatus 100 includes the solid-state imaging device 1A described above as the solid-state imaging device 101.

The optical lens (optical system) 102 forms an image of image light (incident light 106) received from a subject on an imaging surface of the solid-state imaging device 101. As a result, signal charge is accumulated within the solid-state imaging device 101 for a fixed period. The shutter device 103 controls a light applying period and a light shielding period to and from the solid-state imaging device 101. The driving circuit 104 supplies drive signals for controlling a transfer action of the solid-state imaging device 101 and a shutter action of the shutter device 103. Signal transfer of the solid-state imaging device 101 is carried out according to the drive signals (timing signals) supplied from the driving circuit 104. The signal processing circuit 105 performs various types of signal processing for signals (pixel signals) output from the solid-state imaging device 101. Video signals obtained after signal processing are stored in a storage medium such as a memory, or output to a monitor.

The electronic apparatus 100 configured as above reduces crosstalk with use of the solid-state imaging device 101. Accordingly, reliability of the electronic apparatus 100 can improve.

Note that the electronic apparatus 100 is not limited to the camera and may be an electronic apparatus of a different type. For example, the electronic apparatus 100 may be an imaging device such as a camera module for cellular phones or other mobile devices.

Moreover, as the solid-state imaging device 101, the electronic apparatus 100 may include an optical detection device 1 according to either the first embodiment or modifications thereof, or a combination of at least two of the first embodiment and modifications thereof.

### 2. Examples of Application to Moving Body

The technology according to the present disclosure (present technology) is applicable to various products. For example, the technology according to the present disclosure may be implemented as a device mounted on any types of moving bodies selected from cars, electric cars, hybrid-type electric cars, motorcycles, bicycles, personal mobilities, airplanes, drones, vessels, robots, and others.

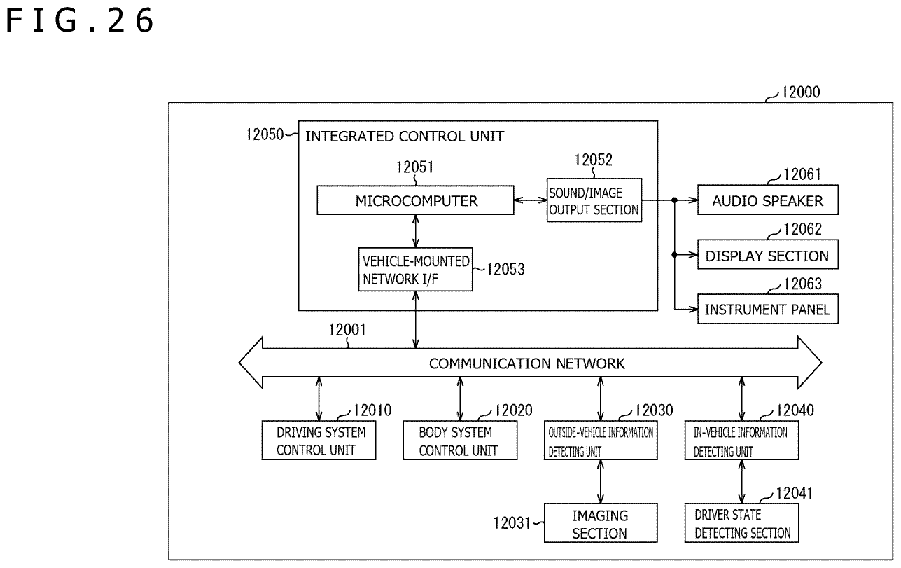

FIG. 26 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 12, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether or not the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 26, an audio speaker 12061, a display section 12062, and an instrument panel 12063 are illustrated as the output device. The display section 12062 may, for example, include at least one of an on-board display and a head-up display.

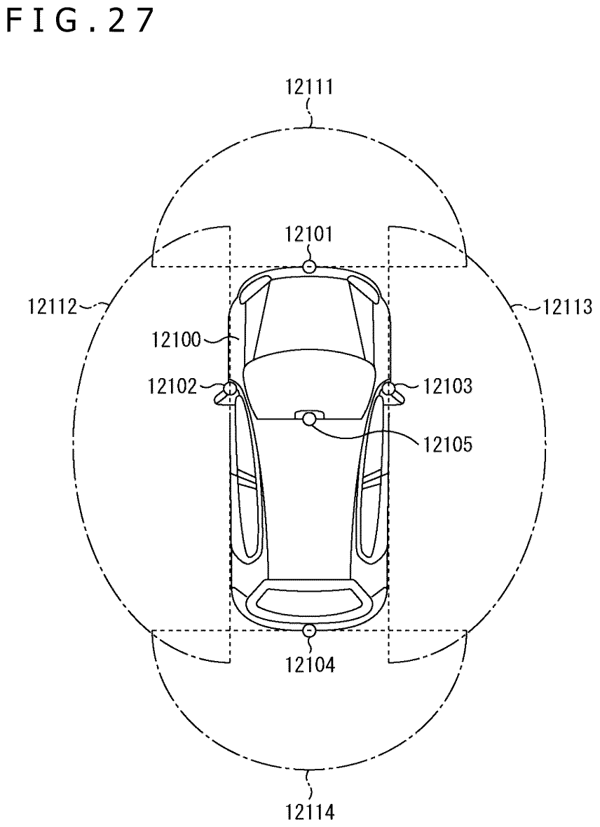

FIG. 27 is a diagram depicting an example of the installation position of the imaging section 12031.

In FIG. 27, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 27 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of the vehicle control system to which the technology according to the present disclosure is applicable has been described above. For example, the technology according to the present disclosure is applicable to the plurality of electronic control units and the imaging section 12031 presented above in the configurations described above. Specifically, each of the shielding bodies (shielding solid film and shielding structures) according to the first to ninth embodiments described above is applicable to the plurality of electronic control units and the imaging section 12031 described above. Reduction of crosstalk is achievable by applying the technology according to the present disclosure to the electronic control units and the imaging section 12031. Accordingly, reliability of the electronic control units and the imaging section 12031 can improve.

### 3. Application Examples to Endoscopic Surgery System

The technology according to the present disclosure (present technology) is applicable to various products. For example, the technology according to the present disclosure may be applied to an endoscopic surgery system.

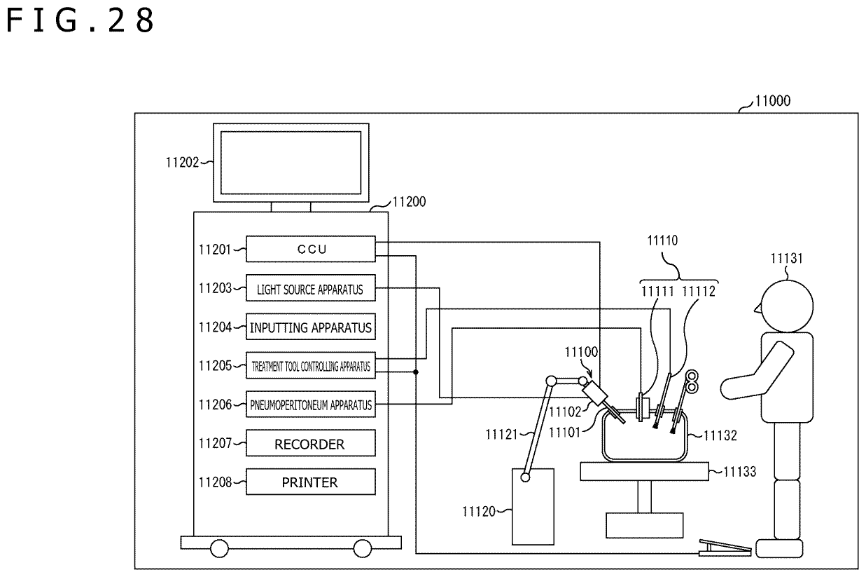

FIG. 28 is a view depicting an example of a schematic configuration of an endoscopic surgery system to which the technology according to an embodiment of the present disclosure (present technology) can be applied.

In FIG. 28, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

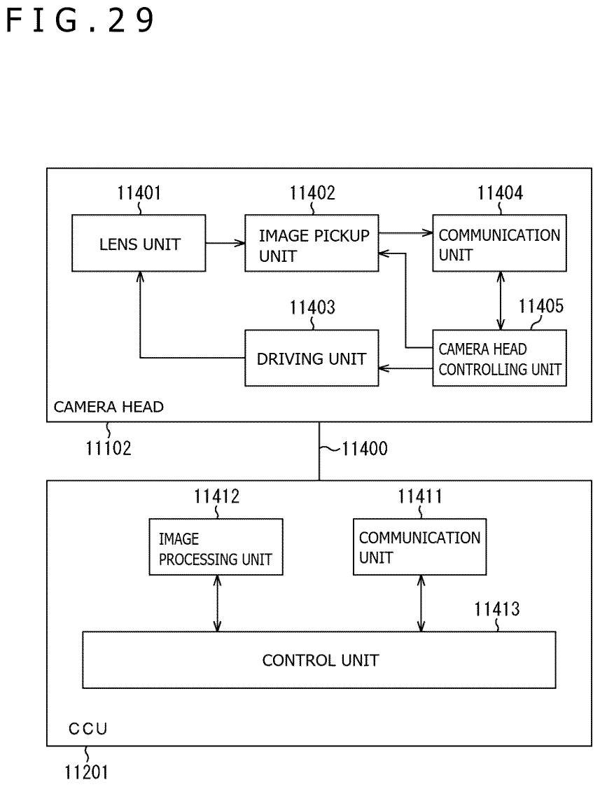

FIG. 29 is a block diagram depicting an example of a functional configuration of the camera head 11102 and the CCU 11201 depicted in FIG. 28.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

One example of the endoscopic surgery system to which the technology according to the present disclosure is applicable has been described above. For example, the technology according to the present disclosure is applicable to the CCU 11201 and the image pickup unit 11402 of the camera head 11102 in the configurations described above. Specifically, each of the shielding bodies (shielding solid film and shielding structures) according to the first to ninth embodiments described above is applicable to the CCU 11201 and the image pickup unit 10402 described above. Reliability of the CCU 11201 and the image pickup unit 10402 can be raised by applying the technology according to the present disclosure to the CCU 11201 and the image pickup unit 10402.

While the endoscopic surgery system has been described herein by way of example, the technology according to the present disclosure may be applied to others such as a microscopic surgery system.

### Other Embodiments

While the present technology has been described above on the basis of the first to ninth embodiments, it should not be considered that statements and drawings constituting some of this disclosure impose limitations to the present technology. Various alternative embodiments, examples, and operation technologies will become apparent to those skilled in the art in light of this disclosure.

Moreover, the present technology is applicable to optical detection devices in general, such as a distance measuring sensor also called a ToF (Time of Flight) sensor and measuring a distance, as well as a solid-state imaging device constituting an image sensor as described above. The distance measuring sensor is a sensor which emits irradiation light toward an object, detects reflection light which is the irradiation light reflected on and returning from a surface of the object, and calculates a distance to the object on the basis of a flight time from emission of the irradiation light to reception of the reflection light. The structure of the first conductor and the second conductor both described above may be adopted as a structure of this distance measuring sensor. In addition, the present technology is applicable to a semiconductor device other than the optical detection device.

Note that the present technology can also take the following configurations.
(1)

An optical detection device including:
a first semiconductor layer that has first and second surfaces located at positions opposite to each other and includes a photoelectric conversion portion for photoelectrically converting light entering from the second surface side;
a second semiconductor layer that includes a transistor, and is provided on the first surface side of the first semiconductor layer;
a third semiconductor layer that includes a transistor, and is provided on the side opposite to the first semiconductor layer side of the second semiconductor layer and overlapped with the second semiconductor layer; and
a shielding body provided between the second semiconductor layer and the third semiconductor layer.
(2)

The optical detection device according to (1) above, in which the shielding body cuts off an electromagnetic field that propagates from one of the second and third semiconductor layers to the other.
(3)

The optical detection device according to (1) or (2) above, in which the shielding body selectively overlaps, in a planar view, with a circuit block including the transistor of at least either of the second and third semiconductor layers.
(4)

The optical detection device according to any one of (1) to (3) above, in which the shielding body is a shielding solid film that has a plate shape and extends two-dimensionally.
(5)

The optical detection device according to any one of (1) to (4) above, in which the shielding solid film is fixed to a surface of the second semiconductor layer on the third semiconductor layer side with interposition of a fixed charge film.
(6)

The optical detection device according to any one of (1) to (5) above, in which the shielding solid film is electrically connected to wiring to which a potential is applied.
(7)

The optical detection device according to any one of (1) to (6) above, further including:
a through contact electrode that penetrates the second semiconductor layer in a thickness direction, and penetrates an opening in the shielding solid film;
a first junction pad provided between the second semiconductor layer and the third semiconductor layer; and
a second junction pad provided on the third semiconductor layer side of the first junction pad, and joined to the first junction pad, in which
at least one of the first and second junction pads has a planar size sufficient for overlapping with whole of the opening in a planar view.
(8)

The optical detection device according to (4) above, further including:
a first wiring layer that is provided on the third semiconductor layer side of the second semiconductor layer, and includes the shielding solid film and the first junction pad; and
a second wiring layer that is joined to the first wiring layer on the second semiconductor layer side of the third semiconductor layer, and includes the second junction pad.
(9)

The optical detection device according to (1) above, in which
the shielding body is a shielding structure that includes
   a first junction pad that is provided between the second semiconductor layer and the third semiconductor layer, and extends in a first direction in a planar view, and
   a second junction pad that is joined to the first junction pad on the third semiconductor layer side of the first metal pad, and extends in the first direction in a planar view, and
the shielding structure is configured such that a set of the first junction pad and the second junction pad located at positions relatively offset from each other in a second direction crossing the first direction are repeatedly arranged.
(10)

The optical detection device according to (9) above, in which the shielding structure further includes a conductor that penetrates the second semiconductor layer in a thickness direction, overlaps with the first metal pad in a planar view, and extends in the first direction.
(11)

The optical detection device according to (9) above, in which the shielding structure further includes conductors that penetrate the second semiconductor layer in a thickness direction, overlap with the first metal pad in a planar view, and are arranged as a plurality of conductors scattered in the first direction.
(12)

The optical detection device according to (9) above, in which
the shielding structure further includes
   a first conductor that penetrates the second semiconductor layer in a thickness direction, overlaps with the first junction pad in a planar view, and extends in the first direction, and
   second conductors that penetrate the second semiconductor layer in the thickness direction, overlap with the first junction pad in a planar view, and are arranged as a plurality of conductors scattered in the first direction.
(13)

The optical detection device according to (1) above, in which
the shielding body is a shielding structure that includes
   a conductor that penetrates the second semiconductor layer in a thickness direction,
   a first junction pad that is provided between the second semiconductor layer and the third semiconductor layer, and extends in a first direction in a planar view, and
   a second junction pad that is joined to the first junction pad on the third semiconductor layer side of the first metal pad, and extends in the first direction in a planar view, and
the shielding structure is configured such that a set of the conductor, the first junction pad, and the second junction pad located at positions relatively offset from each other in a second direction crossing the first direction in a planar view are repeatedly arranged.
(14)

The optical detection device according to (13) above, in which the conductors form a stripe shape that extends in the first direction in a planar view.
(15)

The optical detection device according to (13) above, in which the conductors are arranged as a plurality of conductors scattered in the first direction in a planar view.
(16)

The optical detection device according to (1) above, in which
the shielding body is a shielding structure that includes
   a first junction pad that is provided between the second semiconductor layer and the third semiconductor layer, and extends in a first direction in a planar view,
   a second junction pad that is joined to the first junction pad on the third semiconductor layer side of the first metal pad, and extends in the first direction in a planar view, and
   wiring that is provided on the third semiconductor layer side with respect to the second junction pad, and extends in the first direction in a planar view, and
the shielding structure is configured such that a set of the first and second junction pads and the wiring located at positions relatively offset from each other in a second direction crossing the first direction in a planar view are repeatedly arranged.
(17)

The optical detection device according to (16) above, in which the shielding structure further includes a conductor that penetrates the second semiconductor layer in a thickness direction, overlaps with the first metal pad in a planar view, and extends in the first direction in a planar view.
(18)

The optical detection device according to (16) above, in which the shielding structure further includes conductors that penetrate the second semiconductor layer in a thickness direction, overlap with the first metal pads in a planar view, and are arranged as a plurality of conductors scattered in the first direction in a planar view.
(19)

The optical detection device according to (1) above, in which
the shielding body is a shielding structure that includes
   a conductor that penetrates the second semiconductor layer in a thickness direction,
   a first junction pad that is provided between the second semiconductor layer and the third semiconductor layer, and extends in a first direction in a planar view,
   a second junction pad that is joined to the first junction pad on the third semiconductor layer side of the first metal pad, and extends in the first direction in a planar view, and
   wiring that is provided on the third semiconductor layer side with respect to the second junction pad, and extends in the first direction in a planar view, and
the shielding structure is configured such that a set of the conductor, the first junction pad, the second junction pad, and the wiring located at positions relatively offset from each other in a second direction crossing the first direction in a planar view are repeatedly arranged.
(20)

The optical detection device according to (19) above, in which the conductors form a stripe shape that extends in the first direction in a planar view.
(21)

The optical detection device according to (19) above, in which the conductors are arranged as a plurality of conductors scattered in the first direction in a planar view.
(22)

An electronic apparatus including:
an optical detection device according to any one of (1) to (21);
an optical lens that forms an image of image light received from a subject on an imaging surface of the optical detection device; and
a signal processing circuit that performs signal processing for a signal output from the optical detection device.

The scope of the present technology is not limited to the exemplary embodiments depicted and described, and includes all embodiments offering advantageous effects equivalent to those corresponding to the objects of the present technology. In addition, the scope of the present technology is not limited to combinations of the features of the invention defined by the claims, and can be defined by any desired combinations of specific features included in all of disclosed features.

### REFERENCE SIGNS LIST

1A to 1I: Solid-state imaging device
2: Semiconductor chip
2A: Sensor pixel array section
2B: Peripheral section
3: Sensor pixel
4: Vertical driving circuit
5: Column signal processing circuit
6: Horizontal driving circuit
7: Output circuit
8: Control circuit
10: Pixel drive line
11: Vertical signal line
12: Horizontal signal line
13: Logic circuit
14: Bonding pad
15: Pixel circuit
20: First semiconductor layer
21: Photoelectric conversion region
30: First wiring layer
32: Wiring
40: Second wiring layer
41: Insulation film
42: Wiring
50: Second semiconductor layer
51: Through contact electrode
52, 53: Conductor
55B to 55I: Shielding structure
60: Third wiring layer
62: Wiring
63: Junction pad
70: Fourth wiring layer
72, 72a: Wiring
73: Junction pad
80: Third semiconductor layer
90: Light collection layer
91: Color filter
92: On-chip lens
100: Electronic apparatus
101: Solid-state imaging device
102: Optical system (optical lens)
103: Shutter device
104: Driving circuit
105: Signal processing circuit

What is claimed is:

1. An optical detection device comprising:
a first semiconductor layer that has first and second surfaces located at positions opposite to each other and includes a photoelectric conversion portion for photoelectrically converting light entering from the second surface side;
a second semiconductor layer that includes a transistor, and is provided on the first surface side of the first semiconductor layer;
a third semiconductor layer that includes a transistor, and is provided on a side opposite to the first semiconductor layer side of the second semiconductor layer and overlapped with the second semiconductor layer; and
a shielding body provided between the second semiconductor layer and the third semiconductor layer.

2. The optical detection device according to claim 1, wherein the shielding body cuts off an electromagnetic field that propagates from one of the second and third semiconductor layers to the other.

3. The optical detection device according to claim 1, wherein the shielding body selectively overlaps, in a planar view, with a circuit block including the transistor of at least either of the second and third semiconductor layers.

4. The optical detection device according to claim 1, wherein the shielding body is a shielding solid film that has a plate shape and extends two-dimensionally.

5. The optical detection device according to claim 4, wherein the shielding solid film is fixed to a surface of the second semiconductor layer on the third semiconductor layer side with interposition of a fixed charge film.

6. The optical detection device according to claim 4, wherein the shielding solid film is electrically connected to wiring to which a potential is applied.

7. The optical detection device according to claim 4, further comprising:
a through contact electrode that penetrates the second semiconductor layer in a thickness direction, and penetrates an opening in the shielding solid film;
a first junction pad provided between the second semiconductor layer and the third semiconductor layer; and
a second junction pad provided on the third semiconductor layer side of the first junction pad, and joined to the first junction pad, wherein
at least one of the first and second junction pads has a planar size sufficient for overlapping with whole of the opening in a planar view.

8. The optical detection device according to claim 4, further comprising:
a first wiring layer that is provided on the third semiconductor layer side of the second semiconductor layer, and includes the shielding solid film and the first junction pad; and
a second wiring layer that is joined to the first wiring layer on the second semiconductor layer side of the third semiconductor layer, and includes the second metal pad.

9. The optical detection device according to claim 1, wherein
the shielding body is a shielding structure that includes
a first junction pad that is provided between the second semiconductor layer and the third semiconductor layer, and extends in a first direction in a planar view, and
a second junction pad that is joined to the first junction pad on the third semiconductor layer side of the first metal pad, and extends in the first direction in a planar view, and
the shielding structure is configured such that a set of the first junction pad and the second junction pad located at positions relatively offset from each other in a second direction crossing the first direction are repeatedly arranged.

10. The optical detection device according to claim 9, wherein the shielding structure further includes a conductor that penetrates the second semiconductor layer in a thickness direction, overlaps with the first metal pad in a planar view, and extends in the first direction.

11. The optical detection device according to claim 9, wherein the shielding structure further includes conductors that penetrate the second semiconductor layer in a thickness direction, overlap with the first metal pad in a planar view, and are arranged as a plurality of conductors scattered in the first direction.

12. The optical detection device according to claim 9, wherein
the shielding structure further includes
a first conductor that penetrates the second semiconductor layer in a thickness direction, overlaps with the first junction pad in a planar view, and extends in the first direction, and
second conductors that penetrate the second semiconductor layer in the thickness direction, overlap with the first junction pad in a planar view, and are arranged as a plurality of conductors scattered in the first direction.

13. The optical detection device according to claim 1, wherein
the shielding body is a shielding structure that includes
a conductor that penetrates the second semiconductor layer in a thickness direction,
a first junction pad that is provided between the second semiconductor layer and the third semiconductor layer, and extends in a first direction in a planar view, and
a second junction pad that is joined to the first junction pad on the third semiconductor layer side of the first metal pad, and extends in the first direction in a planar view, and
the shielding structure is configured such that a set of the conductor, the first junction pad, and the second junction pad located at positions relatively offset from each other in a second direction crossing the first direction in a planar view are repeatedly arranged.

14. The optical detection device according to claim 13, wherein the conductors form a stripe shape that extends in the first direction in a planar view.

15. The optical detection device according to claim 13, wherein the conductors are arranged as a plurality of conductors scattered in the first direction in a planar view.

16. The optical detection device according to claim 1, wherein
the shielding body is a shielding structure that includes
a first junction pad that is provided between the second semiconductor layer and the third semiconductor layer, and extends in a first direction in a planar view,
a second junction pad that is joined to the first junction pad on the third semiconductor layer side of the first metal pad, and extends in the first direction in a planar view, and
wiring that is provided on the third semiconductor layer side with respect to the second junction pad, and extends in the first direction in a planar view, and
the shielding structure is configured such that a set of the first and second junction pads and the wiring located at positions relatively offset from each other in a second direction crossing the first direction in a planar view are repeatedly arranged.

17. The optical detection device according to claim 16, wherein the shielding structure further includes a conductor that penetrates the second semiconductor layer in a thickness direction, overlaps with the first metal pad in a planar view, and extends in the first direction in a planar view.

18. The optical detection device according to claim 16, wherein the shielding structure further includes conductors that penetrate the second semiconductor layer in a thickness direction, overlap with the first metal pads in a planar view, and are arranged as a plurality of conductors scattered in the first direction in a planar view.

19. The optical detection device according to claim 1, wherein
the shielding body is a shielding structure that includes
a conductor that penetrates the second semiconductor layer in a thickness direction,
a first junction pad that is provided between the second semiconductor layer and the third semiconductor layer, and extends in a first direction in a planar view,
a second junction pad that is joined to the first junction pad on the third semiconductor layer side of the first metal pad, and extends in the first direction in a planar view, and
wiring that is provided on the third semiconductor layer side with respect to the second junction pad, and extends in the first direction in a planar view, and
the shielding structure is configured such that a set of the conductor, the first junction pad, the second junction pad, and the wiring located at positions relatively offset from each other in a second direction crossing the first direction in a planar view are repeatedly arranged.

20. The optical detection device according to claim 19, wherein the conductors form a stripe shape that extends in the first direction in a planar view.

21. The optical detection device according to claim 19, wherein the conductors are arranged as a plurality of conductors scattered in the first direction in a planar view.

22. An electronic apparatus comprising:
an optical detection device;
an optical lens that forms an image of image light received from a subject on an imaging surface of the optical detection device; and
a signal processing circuit that performs signal processing for a signal output from the optical detection device, wherein
the optical detection device includes
a first semiconductor layer that has first and second surfaces located at positions opposite to each other and includes a photoelectric conversion portion for photoelectrically converting light entering from the second surface side,
a second semiconductor layer that includes a transistor, and is provided on the first surface side of the first semiconductor layer,
a third semiconductor layer that includes a transistor, and is provided on the side opposite to the first semiconductor layer side of the second semiconductor layer and overlapped with the second semiconductor layer, and
a shielding body provided between the second semiconductor layer and the third semiconductor layer.
